(19) United States
(12) Patent Application Publication
(10) Pub. No.: US 2022/0328591 A1
(43) Pub. Date: Oct. 13, 2022

(54) DISPLAY PANEL AND DISPLAY DEVICE

(71) Applicant: Xiamen Tianma Display Technology Co., Ltd., Xiamen (CN)

(72) Inventor: Bin SUN, Xiamen (CN)

(73) Assignee: Xiamen Tianma Display Technology Co., Ltd., Xiamen (CN)

(21) Appl. No.: 17/851,978

(22) Filed: Jun. 28, 2022

(30) Foreign Application Priority Data
Apr. 2, 2022 (CN) 202210350849.6

(51) Int. Cl. H01L 27/32; H01L 51/52

(52) U.S. Cl. CPC H01L 27/3262; H01L 51/5284

(57) ABSTRACT

Provided are a display panel and a display device. The display panel includes a substrate and multiple pixel circuits located on a side of the substrate. Each of at least part of the multiple pixel circuits includes a first transistor. The first transistor includes at least two active layers having different mobilities. At least two active layers having different mobilities include a first active layer and a second active layer which are laminated. The mobility of the first active layer is larger than the mobility of the second active layer. Therefore, the structure and the manufacturing process of the display panel can be simplified, facilitating the lightweight and low cost of the display panel.

### CROSS-REFERENCE TO RELATED APPLICATION(S)

This application claims priority to Chinese Patent Application No. 202210350849.6 filed Apr. 2, 2022, the disclosure of which is incorporated herein by reference in its entirety.

### TECHNICAL FIELD

The present disclosure relates to the field of display technologies and, in particular, to a display panel and a display device.

### BACKGROUND

With the development of display technologies, the requirement for the display function of a display device is getting higher and higher. Moreover, along with the higher requirement for the display function of the display device, more and more performances of device structures in a display panel of the display device are required.

A related display panel is generally provided with a pixel circuit to control display units in the display panel to display and emit light. The pixel circuit is generally composed of thin film transistors. In the related art, the thin film transistors cannot be characterized by low power consumption, high reliability and low leakage current in the off state, and thus the requirements for high-quality display luminance of the display panel cannot be satisfied.

### SUMMARY

The present disclosure provides a display panel and a display device so that a pixel circuit in the display panel can be characterized by low power consumption, high reliability and low leakage current in the off state, thereby satisfying the requirements for high-quality display luminance of the display panel.

In a first aspect of the present disclosure, a display panel is provided. The display panel includes a substrate and multiple pixel circuits located on a side of the substrate.

Each of at least part of the multiple pixel circuits includes a first transistor. The first transistor includes at least two active layers having different mobilities.

The at least two active layers having different mobilities includes a first active layer and a second active layer which are laminated. The mobility of the first active layer is larger than the mobility of the second active layer.

In another aspect of the present disclosure, a display device is provided. The display device includes the preceding display panel.

### BRIEF DESCRIPTION OF DRAWINGS

To illustrate solutions in embodiments of the present disclosure more clearly, the drawings used in description of the embodiments will be briefly described below. Apparently, the drawings described below illustrate only part of embodiments of the present disclosure, and those of ordinary skill in the art may obtain other drawings based on the drawings described below on the premise that no creative work is done.

FIG. 1 is a view illustrating the structure of films of a display panel in the related art.

FIG. 2 is a top view of a display panel according to an embodiment of the present disclosure.

FIG. 3 is a view illustrating the structure of films of a display panel according to an embodiment of the present disclosure.

FIG. 4 is a view illustrating the structure of films of another display panel according to an embodiment of the present disclosure.

FIGS. 5 to 15 are views illustrating the structure of films of another display panel according to an embodiment of the present disclosure.

FIG. 16 is a view illustrating the structure of a pixel circuit according to an embodiment of the present disclosure.

FIGS. 17 to 19 are views illustrating the structure of films of another display panel according to an embodiment of the present disclosure.

FIG. 20 is a view illustrating the structure of another pixel circuit according to an embodiment of the present disclosure.

FIGS. 21 to 31 are views illustrating the structure of films of another display panel according to an embodiment of the present disclosure.

FIG. 32 is a top view of another display panel according to an embodiment of the present disclosure.

FIGS. 33 to 34 are views illustrating the structure of films of another display panel according to an embodiment of the present disclosure.

FIG. 35 is a view illustrating the structure of a display device according to an embodiment of the present disclosure.

### DETAILED DESCRIPTION

The solutions in embodiments of the present disclosure will be clearly and completely described in conjunction with the drawings in the embodiments of the present disclosure from which the solutions will be better understood by those skilled in the art. Apparently, the embodiments described below are part, not all, of the embodiments of the present disclosure. Based on the embodiments described herein, all other embodiments obtained by those skilled in the art on the premise that no creative work is done are within the scope of the present disclosure.

It is to be noted that the terms “first”, “second” and the like in the description, claims and drawings of the present disclosure are used to distinguish between similar objects and are not necessarily used to describe a particular order or sequence. It can be understood that the data used in this way is interchangeable where appropriate so that the embodiments of the present disclosure described herein may also be implemented in a sequence not illustrated or described herein. In addition, the terms “comprising”, “including” or any other variations thereof described herein are intended to encompass a non-exclusive inclusion. For example, a process, method, system, product or device that includes a series of steps or units not only includes the expressly listed steps or units but may also include other steps or units that are not expressly listed or are inherent to such process, method, product or device.

As described in the background, characteristic optimization of a transistor in a display panel is the key to improve the light-emitting effect of the display panel. For example, a pixel circuit in the display panel for driving a display element to emit light typically includes multiple transistors. Different transistors need to satisfy different characteristic requirements. For example, a driving transistor having the driving function needs to satisfy the characteristics of low power consumption and high reliability, while a switching transistor having the switching function needs to satisfy the requirement of low cut-off current. The low-temperature polysilicon material has a high mobility (100 cm²/V s or above) so that the transistor using the low-temperature polysilicon material as an active layer can be characterized by low power consumption and high reliability. Therefore, the transistor using the low-temperature polysilicon material as the active layer is generally used as the driving transistor of the display element, the transistor in a gate driving circuit and/or a multiplexer (MUX) circuit and the like. Since the oxide semiconductor material has a larger band gap than the silicon material, electrons cannot cross the band gap in the cut-off state so that the cut-off current of the transistor using the oxide semiconductor material as the active layer is very low. Therefore, the transistor using the oxide semiconductor material as the active layer is suitable for the switching transistor having a shorter on time and a longer cut-off time. On this basis, to enable each transistor in the pixel circuit of the display panel to have the excellent characteristics matching the functions of the transistor, in the related art, the transistor using the low-temperature polysilicon material as the active layer and the transistor using the oxide semiconductor material as the active layer are generally formed on the same substrate.

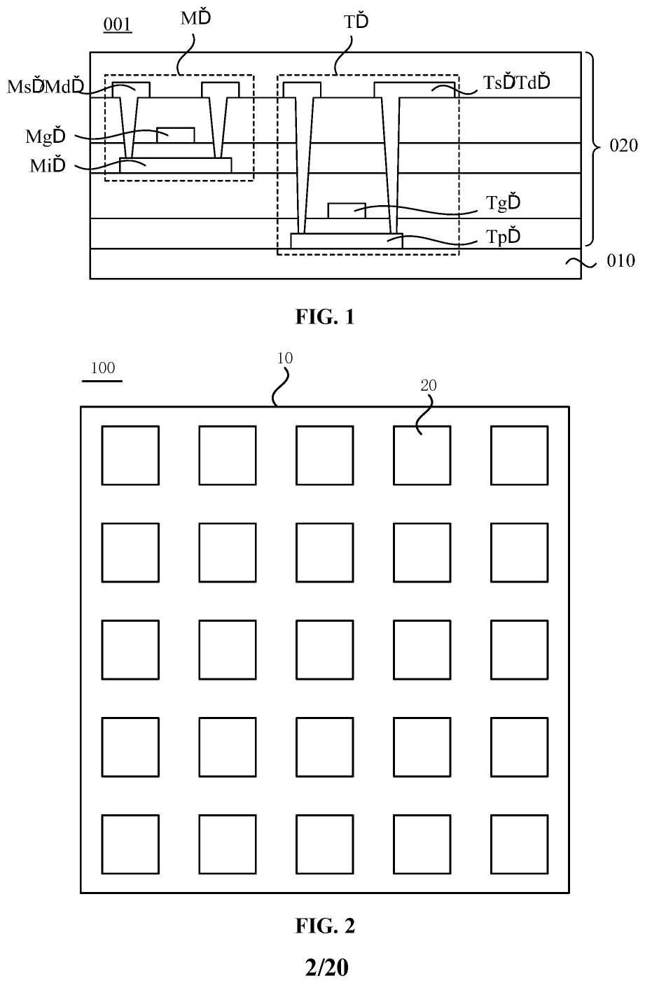

As shown in FIG. 1, FIG. 1 is a view illustrating the structure of films of a display panel in the related art. The display panel 001 includes a substrate 010 and a pixel circuit 020 located on the substrate 010. The pixel circuit 020 may include a driving transistor T′ and at least one switching transistor M′ (only one switching transistor is illustratively shown in the figure). An active layer Tp′ of the driving transistor T′ uses the low-temperature polysilicon material and an active layer Mi′ of the at least one switching transistor M′ uses the oxide semiconductor material. In this case, the primary manufacturing processes of the thin film transistor in the display panel include the steps described below. The active layer Tp′ of the driving transistor T′ is formed on the substrate 010 by using the low-temperature polysilicon material. A gate Tg′ of the driving transistor T′ is formed on a side of the active layer Tp′ of the driving transistor T′ facing away from the substrate 010. A corresponding gate insulating layer is disposed between the active layer Tp′ of the driving transistor T′ and the gate Tg′ of the driving transistor T′. The active layer Mi′ of the switching transistor M′ is formed by using the oxide semiconductor material on a side of the gate Tg′ of the driving transistor T′ facing away from the substrate 010. An insulating layer is also disposed between the gate Tg′ of the driving transistor T′ and the active layer Mi′ of the switching transistor M′. A gate Mg′ of the switching transistor M′ is formed on a side of the active layer Mi′ of the switching transistor M′ facing away from the substrate 010. A corresponding gate insulating layer is also disposed between the active layer Mi′ of the switching transistor M′ and the gate Mg′ of the switching transistor M′. Finally, a source/drain electrode layer is formed on a side of the gate Mg′ of the switching transistor M′ facing away from the substrate 010. A corresponding insulating layer is also disposed between the source/drain electrode layer and the gate Mg′ of the switching transistor M′. Moreover, the source/drain electrode layer includes both source/drain electrodes Ts′/Td′ of the driving transistor T′ and source/drain electrodes Ms′/Md′ of the switching transistor M′. The source/drain electrodes Ts′/Td′ of the drive transistor T′ need to be connected to the active layer Tp′ of the drive transistor T′ by extending through vias on all of the insulating layers between the source/drain electrode layer and the active layer Tp′ of the drive transistor T′. The source/drain electrodes Ms′/Md′ of the switching transistor M′ need to be connected to the active layer Mi′ of the switching transistor M′ by extending through vias on all of the insulating layers between the source/drain electrode layer to the active layer Mi′ of the switching transistor M′. In this way, the driving transistor T′ and the switching transistor M′ that have different active layers are formed on the same substrate 010 separately so that each transistor of the pixel circuit 020 can have the excellent characteristics.

However, in the related art, a transistor having the lower leakage current in the off state is not characterized by low power consumption, while a transistor characterized by the low power consumption cannot have the lower leakage current in the off state. Moreover, in the related art, various function layers of the transistor satisfying different characteristic requirements are formed in different films, causing the display panel to have more films, thereby not facilitating the lightweight design of the display panel. In addition, various function layers of the transistor satisfying different characteristic requirements are formed in different films and different films need to be manufactured in different manufacturing processes, as a result, the display panel to have complicate manufacturing processes, not facilitating improving the production efficiency of the display panel and not facilitating the low cost of the display panel.

To solve the preceding problems, embodiments of the present disclosure provide a display panel. The display panel includes a substrate and multiple pixel circuits located on a side of the substrate. Each of at least part of the multiple pixel circuits includes a first transistor. The first transistor includes at least two active layers having different mobilities. At least two active layers having different mobilities include a first active layer and a second active layer which are laminated. The mobility of the first active layer is larger than the mobility of the second active layer.

With the solutions of the embodiments of the present disclosure, the first transistor of the each of the at least part of the multiple pixel circuits in the display panel is configured to include at least two active layers of having different mobilities. Among the at least two active layers, the first active layer has a larger mobility and the second active layer has a smaller mobility so that the first transistor can not only be characterized by reliability and low power consumption possessed by the transistor having the high mobility active layer, but also be characterized by low cut-off current possessed by the transistor having the low mobility active layer. In this manner, in the case where the pixel circuit includes the first transistor, display units driven by the pixel circuit can stably and accurately emit light, thereby further improving the display quality of the display panel. Moreover, since the first transistor has the performance of both the transistor having the high mobility active layer and the transistor having the low mobility active layer, it is unnecessary to manufacture the transistors having different characteristics in different films, facilitating reducing the number of films in the display panel, and further facilitating the lightweight design of the display panel. In addition, when the number of films in the display panel is reduced, it is conductive to simplifying the manufacturing process of the display panel, thereby facilitating reducing the production cost of the display panel and improving the production efficiency of the display panel.

The above is the core concepts of the present disclosure, the solutions in the embodiments of the present disclosure will be clearly and completely described in conjunction with drawings in the embodiments of the present disclosure. Based on the embodiments of the present disclosure, all other embodiments obtained by those skilled in the art without creative work are within the scope of the present disclosure.

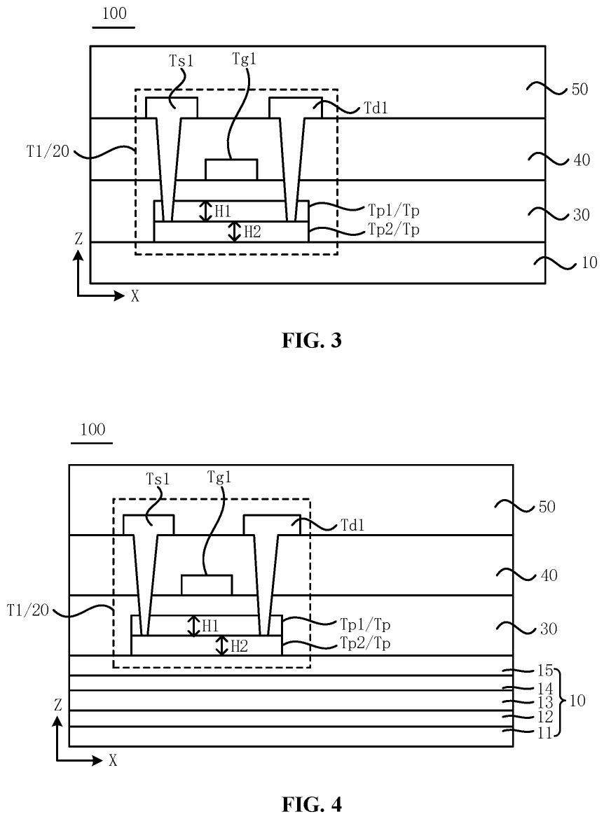

FIG. 2 is a top view of a display panel according to an embodiment of the present disclosure. FIG. 3 is a view illustrating the structure of films of a display panel according to an embodiment of the present disclosure. Referring to FIGS. 2 and 3, the display panel 100 includes a substrate 10 and multiple pixel circuits 20 located on a side of the substrate 10. The multiple pixel circuits 20 may be disposed in an array on a side of the substrate 10. Each of at least part of the multiple pixel circuits 20 includes a first transistor T1. The first transistor T1 includes at least two active layers Tp having different mobilities. At least two active layers Tp having different mobilities include a first active layer Tp1 and a second active layer Tp2 which are laminated. The mobility of the first active layer Tp1 is larger than the mobility of the second active layer Tp2.

The substrate 10 may be transparent, translucent or opaque. The substrate 10 may be a rigid substrate such as a glass substrate, and may also be a flexible substrate so that the substrate 10 has the characteristics of stretchable, foldable, bendable or flexible. In this case, the substrate 10 may be formed from any suitable flexible insulating material such as polyimide (PI), polycarbonate (PC), polyether sulfone (PES), polyethylene terephthalate (PET), polyethylene naphthalate (PEN), polyarylate (PAR), glass fiber reinforced plastic (FRP) or another polymer material. In an embodiment, as shown in FIG. 4, in the case where the substrate 10 is flexible, the substrate 10 plays a role of blocking oxygen and water vapor, preventing water, oxygen or impurities from diffusing through the substrate 10. In this case, the substrate 10 may include an organic layer 44, an inorganic layer 12, an organic layer 13, an inorganic layer 14 and a buffer layer 15 from bottom to top. Correspondingly, in the case where the substrate 10 is rigid, the buffer layer may also be disposed between glass and a device structure thereon, thereby enhancing the adhesion between the device structure formed on the substrate 10 and the substrate 10, and blocking the alkaline component leaking from the substrate 10. It can be noted that the buffer layer is not indispensable, and whether the buffer layer needs to be disposed can be determined according to the type and the material of the substrate 10, and the structure and the type of the device on the substrate 10. On the premise of satisfying the core inventive points of the embodiments of the present disclosure, the structure and the performance of the substrate 10 is not limited by the embodiments of the present disclosure.

The mobility of the active layer in the transistor can determine the performance of the transistor to a certain extent. Therefore, to a certain extent, the larger the mobility of the active layer, the higher the conductivity of the transistor, the smaller the resistivity of the transistor, the larger the current carrying capacity of the transistor and the faster the response speed of the transistor so that the transistor including the active layer having the larger mobility is characterized by low power consumption and high reliability. On the contrary, in view of the transistor including the active layer having the smaller mobility, the conductivity of the transistor is lower, the resistivity of the transistor is larger, and the energy required for the carrier transition of the transistor is larger. As a result, in the case where the transistor including the active layer having the smaller mobility is in an off state, carriers in the active layer cannot transit or only a small number of the carriers can successfully transit due to the insufficient excitation energy, thereby further causing the transistor including the active layer having the smaller mobility to have the characteristic of low cut-off current. Therefore, as shown in FIG. 3, in the case where the first transistor T1 of the pixel circuit 20 includes at least two active layers Tp having different mobilities, the at least two active layers Tp in the first transistor T1 may have the characteristics of both the transistor having the larger mobility and the transistor having the smaller mobility. Alternatively, the at least two active layers Tp of the first transistor T1 can neutralize the characteristics of the transistor having the larger mobility and the transistor having the smaller mobility so that the first transistor T1 can not only be used as a driving transistor, but also be used as a switching transistor. In this manner, in the case where the pixel circuit includes the first transistor, a light-emitting element 80 driven by the pixel circuit can stably and accurately emit light, thereby further improving the display quality of the display panel. Moreover, compared with the case where different active layers are disposed in different processes and function layers, and the insulating layers are disposed between different function layers in the related art shown in FIG. 1, the first active layer Tp1 having the larger mobility and the second active layer Tp2 having the smaller mobility are laminated among the at least two active layers Tp of the first transistor, thereby facilitating simplifying the structure of the display panel 100, simplifying the manufacturing process of the display panel 100, further facilitating the lightweight design of the display panel 100, improving the production efficiency of the display panel 100 and reducing the manufacturing cost of the display panel 100.

It can be understood that the display panel may be a self-luminous display panel or a non-self-luminous display panel that needs a backlight module to provide a backlight. In the case where the display panel is the self-luminous display panel, the display unit thereof may include but is not limited to an organic light-emitting diode (OLED), a micro-light-emitting diode (micro-LED) and a mini-light-emitting diode (mini-LED), and the specific type of the display panel is not limited by the embodiments of the present disclosure.

The mobility of the first active layer Tp1 of the first transistor T1 may be larger than or equal to the mobility of the active layer manufactured by using the low-temperature polysilicon material in the related art. The mobility of the second active layer Tp1 of the first transistor T1 may be smaller than or equal to the mobility of the active layer manufactured by using the oxide semiconductor material in the related art. Alternatively, the first active layer Tp1 of the first transistor T1 may be between the mobility of the active layer manufactured by using the low-temperature polysilicon material in the related art and the mobility of the active layer manufactured by using the oxide semiconductor material in the related art The second active layer Tp1 of the first transistor T1 may also be between the mobility of the active layer manufactured by using the low-temperature polysilicon material in the related art and the mobility of the active layer manufactured by using the oxide semiconductor material in the related art. It can be noted that the level of the mobility of the first active layer Tp1 or the second active layer Tp2 is a relative concept. On the premise that the active layer Tp of the first transistor T1 can be characterized by low power consumption, high reliability and relatively small cut-off current, the specific value of the mobility of each active layer Tp of the first transistor T1 is not specifically limited by the embodiments of the present disclosure.

In an embodiment, each active layer Tp of the first transistor T1 includes an oxide semiconductor. The oxide semiconductor includes indium. The indium content of the first active layer Tp1 is larger than the indium content of the second active layer Tp2.

In an embodiment, the oxide semiconductor has the advantages of low manufacturing process temperature and good uniformity. For example, the first transistor T1 may be manufactured in a manner of magnetron sputtering so that the manufacturing process of the first transistor T1 using the oxide semiconductor as the active layer is easy and has good uniformity, thereby facilitating simplifying the manufacturing process of the display panel 100 and reducing the manufacturing cost of the display panel 100. In an embodiment, the oxide semiconductor includes, but is not limited to, indium gallium zinc oxide (InGaZnO, IGZO). In this case, the composition of each active layer Tp in the first transistor T1 can be considered to be the same. In view of the oxide semiconductor material containing indium, the indium content can determine the mobility of electrons (carriers) in this oxide semiconductor. The higher the indium content in the oxide semiconductor, the larger the carrier mobility. That is, the larger the value of m, the larger the mobility. On this basis, the indium content of the first active layer Tp1 may be configured to be larger than the indium content of the second active layer Tp2 so that the first active layer Tp1 has the larger mobility and the second active layer Tp2 has the smaller mobility.

It can be understood that in the case where each active layer Tp of the first transistor T1 is the oxide semiconductor containing indium, the indium content in each active layer Tp increases as the mobility of each active layer Tp increases. The indium content can be configured as needed, and the embodiments of the present disclosure do not limit thereto.

It is to be noted that the active layers Tp having different mobilities in the first transistor T1 may also have different compositions. That is, the first active layer Tp1 having the larger mobility includes a component that contributes more to the carrier mobility, and the second active layer Tp2 having the smaller mobility includes a component that contributes less to the carrier mobility.

In another embodiment, in the case where each active layer of the first transistor includes an oxide semiconductor, the oxide semiconductor may include InGaXO, where X includes one of Zn, Zn—Sn and Sn. In this case, X in the first active layer Tp1 is different from X in the second active layer TP2.

In an embodiment, in the oxide semiconductor, the mobility of indium gallium zinc oxide (InGaZnO, IGZO) is generally smaller than the mobility of indium gallium zinc tin oxide (InGaZnSnO, IGZTO), and the mobility of the indium gallium zinc tin oxide (InGaZnSnO, IGZTO) is generally smaller than the mobility of indium gallium tin oxide (InGaSnO, IGTO). In this way, in the case where X in the first active layer TP1 is Zn—Sn, that is, the oxide semiconductor of the first active layer TP1 is the indium gallium zinc tin oxide (InGaZnSnO, IGZTO), the oxide semiconductor of the second active layer Tp2 is the indium gallium zinc oxide (InGaZnO, IGZO) to satisfy the characteristic that the mobility of the first active layer TP1 is larger than the mobility of the second active layer Tp2. In the case where X in the first active layer TP1 is Sn, that is, the oxide semiconductor of the first active layer TP1 is the indium gallium tin oxide (InGaSnO, IGTO), the oxide semiconductor of the second active layer Tp2 is the indium gallium zinc oxide (InGaZnO, IGZO) or the indium gallium zinc tin oxide (InGaZnSnO, IGZTO), in this case, the characteristic that the mobility of the first active layer TP1 is larger than the mobility of the second active layer Tp2 can also be satisfied.

It is to be noted that on the premise that the mobility of the first active layer Tp1 is larger than the mobility of the second active layer Tp2, the composition of each active layer Tp in the first transistor T1 is not specifically limited by the embodiments of the present disclosure.

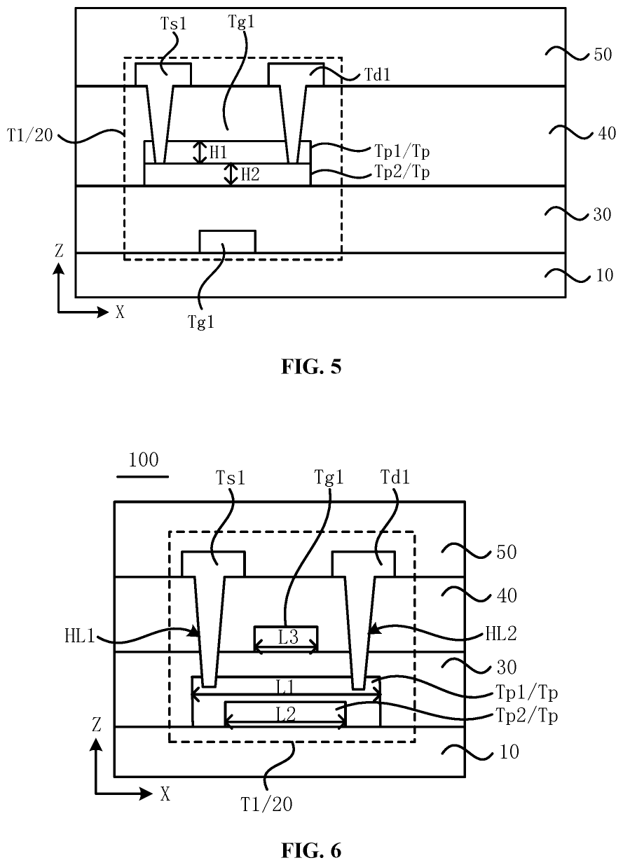

It can be understood that in the case where the at least two active layers Tp of the first transistor T1 include the first active layer Tp1 having the larger mobility and the second active layer Tp2 having the smaller mobility, as shown in FIG. 2, the second active layer Tp1 may be located on a side of the first active layer Tp2 close to the substrate 10; or as shown in FIG. 5, the second active layer Tp1 may also be located on a side of the first active layer Tp2 facing away from the substrate 10, and the embodiments of the present disclosure do not specifically limit thereto.

In addition, the first transistor T1 should also include a first source Ts1, a first drain Td1 and a first gate Tg1. Correspondingly, the active layer Tp of the first transistor T1 may include a source region, a drain region, and a channel region located between the source region and the drain region. In the case where the first transistor T1 is in the off state, two PN junctions form among the source region, the channel region, and the drain region of the active layer Tp. The first source Ts1 may be in contact with the source region of the active layer Tp through a via. The first drain Td1 may be in contact with the drain region of the active layer Tp through a via. The first gate Tg1 overlaps the channel region of the active layer Tp in a thickness direction Z of the display panel 100. In the case where corresponding electrical signals are applied to the first gate Tg1 and the first source Ts of the first transistor T1, for example, a voltage difference Vgs between the electrical signal applied to the first gate Tg1 and the electrical signal applied to the first source Ts1 satisfies |Vgs|≥|Vth| (Vth1 denotes a threshold voltage of the first transistor T1), an electric field generated in the gate insulating layer 30 between the first gate Tg1 and the active layer Tp can be acted on the active layer Tp, and the carriers in the active layer Tp can be attracted so that the carriers in the channel region of the active layer Tp are aggregated to form a carrier layer so that the source region and the drain region of the active layer Tp are communicated through the carrier layer of the channel region, and the first source Ts1 and the first drain Td1 are turned on, thereby enabling the first transistor T1 to be in an on state. On the contrary, if the electric field in the gate insulating layer 30 is insufficient to control minority carriers in the active layer Tp to be aggregated into a minority carrier layer, and the first source Ts1 and the first drain Td1 cannot be communicated, thereby enabling the first transistor T1 to be in the off state.

It can be understood that as shown in FIG. 3, the first gate Tg1 may be located on a side of the active layer Tp facing away from the substrate 10. In this case, the first transistor T1 is a top gate transistor. Thus, in the manufacturing process of the display panel, a semiconductor layer corresponding to each active layer Tp of the first transistor T1 may be formed on the substrate 10; after the semiconductor layer is patterned, the gate insulating layer 30 and a film corresponding to the first gate Tg1 may be sequentially formed on the patterned semiconductor layer, the gate insulating layer 30 and the first gate Tg1 are patterned to expose the source region and the drain region in the active layer Tp; and the source region and the drain region are doped with the first gate Tg1 as a mask to form the active layer Tp including the source region, the channel region and the drain region. In this manner, it is unnecessary to provide additional masks for doping the source region and the drain region in the active layer Tp, thereby further reducing the number of masks used and reducing the manufacturing cost of the display panel. Alternatively, as shown in FIG. 5, the first gate Tg may also be located on a side of the active layer Tp close to the substrate 10. In this case, the first transistor T1 is a bottom gate transistor.

If the buffer layer needs to be disposed between the substrate 10 and the device structure thereon, the gate insulating layer between the first gate Tg1 of the first transistor T1 and the active layer Tp of the first transistor T1 may be multiplexed into the buffer layer, facilitating reducing the number of films of the display panel 100, simplifying the structure of the display panel 100, and facilitating the lightweight, low cost and high production efficiency of the display panel 100. Moreover, the first gate Tg1 is configured to receive the electrical signal so that a metal material or an alloy material having the conductive function is generally selected and used in the first gate Tg1. The metal material and the alloy material generally have a light shielding effect. Therefore, the first gate Tg1 located on a side of the active layer Tp close to the substrate 10 has a certain light shielding function, and thus light incident from the substrate 10 side can be blocked, thereby preventing this part of light from entering the channel region of the active layer Tp and affecting the carriers in the channel region of the active layer Tp, facilitating improving the stability and reliability of the first transistor T1. On this basis, whether the first transistor T1 is the top gate transistor or the bottom gate transistor, the first transistor T1 has corresponding advantages. On the premise of satisfying the core inventive points of the embodiments of the present disclosure, the type of the first transistor T1 is not specifically limited by the embodiments of the present disclosure.

In an embodiment, reference to any one of FIGS. 3 and 5, in the case where the first transistor T1 includes the first gate Tg1, this first gate Tg1 may be located on a side of the first active layer Tp1 facing away from the second active layer Tp2.

In an embodiment, the first gate Tg1 is disposed on a side of the first active layer Tp1 facing away from the second active layer Tp2, in the case where the corresponding electrical signals are applied to the first gate Tg1 and the first source Ts to generate the electric field acting on the active layer Tp, this electric field can act on the first active layer Tp1 first and the carriers in the active layer Tp1 having the larger mobility can be quickly aggregated to form the carrier layer so that the first source Ts1 and the first drain Td1 can be quickly turned on, and further the first transistor T1 has a faster response speed. Moreover, the first active layer Tp1 has the larger mobility, so that the first source Ts1 and the first drain Td1 can be turned on as long as a smaller electric field acts on the first active layer Tp1. That is, the first source Ts1 and the first drain Td1 can be turned on as long as the voltage difference between the electrical signal applied to the first gate Tg1 and the electrical signal applied to the first source Ts has a smaller value, thereby facilitating the low power consumption of the first transistor T1. In addition, in the case where the channel type of the first active layer Tp1 and the channel type of the second active layer Tp2 of the first transistor are both N-type, the second active layer Tp2 has a smaller mobility so that the electrons in the second active layer Tp2 need a larger electric field to be attracted to the surface layer of the second active layer Tp2. On the contrary, in the case where the channel type of the first active layer Tp1 and the channel type of the second active layer Tp2 of the first transistor are both P-type, electron holes in the second active layer Tp2 need a larger electric field to be attracted to the surface layer of the second active layer Tp2 so that the electric field generated in the gate insulating layer 30 is insufficient to cause the carriers in the channel region of the second active layer Tp2 to be aggregated in the case where the first transistor T1 is in the off state. Moreover, the electric field in the channel region of the second active layer Tp2 can suppress the carriers in the channel region of the first active layer Tp1 to be aggregated so that the carriers in the channel region of the first active layer Tp1 cannot be aggregated, or the number of carriers aggregated can be significantly reduced, thereby enabling the first transistor T1 to have a smaller leakage current in the case where the first transistor T1 is in the off state. In this way, the first transistor T1 can be characterized by low power consumption, high reliability, and low off-state leakage current so that in the case where the pixel circuit including the first transistor T1 is configured to control the light-emitting element 80 in the display panel 100 to emit the light, the light-emitting accuracy and stability of the light-emitting element 80 can be improved, and thus the display quality of the display panel 100 can be improved.

It is to be noted that the case where the first active layer is located on a side of the second active layer close to the substrate is similar to the case where the first active layer is located on a side of the second active layer facing away from the substrate. For ease of description, the solutions in the embodiments of the present disclosure are described below by means of examples in which the first active layer is located on a side of the second active layer facing away from the substrate in the embodiments of the present disclosure.

It can be understood that FIGS. 3 to 5 are merely exemplary drawings of the embodiments of the present disclosure. FIGS. 3 to 5 merely exemplarily illustrates that the first transistor T1 is used as the driving transistor to provide a driving current for a light-emitting element 80. In the embodiments of the present disclosure, the first transistor T1 may also be other transistors, and the embodiments of the present disclosure do not specifically limit thereto.

The drawings corresponding to the preceding embodiments merely illustrate by means of examples that the dimension of the first active layer Tp1 of the first transistor T1 is equivalent to the dimension of the second active layer Tp2 of the first transistor T1 in a direction X parallel to a plane where the substrate 10 is located, while in this embodiment of the present disclosure, the dimension of the first active layer Tp1 of the first transistor T1 may be different from the dimension of the second active layer Tp2 of the first transistor T1.

In an embodiment, as shown in FIG. 6, in a thickness direction Z of the display panel 100, the first gate Tg overlaps both the first active layer Tp1 and the second active layer Tp2. In the first direction X, the dimension L1 of the first active layer Tp1 is larger than the dimension L2 of the second active layer Tp2. The first direction X is parallel to the plane where the substrate 100 is located.

In an embodiment, the moving speed of the carriers in the active layer Tp is related to the strength of the electric field received by the carriers and the mobility of the active layer Tp. That is, in the case where the electric field acting on the first active layer Tp1 is equivalent to the electric field acting on the second active layer Tp2, the directional moving speed of the carriers in the first active layer TP1 having the larger mobility is larger than the directional moving speed of the carriers in the second active layer TP2. In this way, the dimension of the first active layer TP1 in the first direction X is configured to be larger than the dimension of the second active layer TP2 in the first direction so that in the thickness direction of the display panel 100, the kinetic energy of the carriers in a region of the first active layer Tp1 that does not overlap the second active layer TP2 is limited only by the mobility of the first active layer Tp1, ensuring the carriers in this region to have a larger moving speed, thereby ensuring the first transistor T1 to have a faster response speed, improving the stability and reliability of the first transistor T1, facilitating improving the stability and accuracy of the display luminance of the display unit controlled by the pixel circuit including the first transistor T1 and improving the display quality of the display panel 100.

In an embodiment, referring to FIG. 6, in the case where the first transistor T1 also includes the first source Ts1 and the first drain Td1, in the thickness direction Z of the display panel 100, an overlapping region of the first active layer Tp1 with the first gate Tg1 is a first channel region. The first active layer Tp1 also includes a first source region and a first drain region disposed in the first direction X and located on two opposite sides of the first channel region. The first source Ts1 is electrically connected to the first source region through a first via HL1. The first drain Td1 is electrically connected to the first drain region through a second via HL2. In the thickness direction Z of the display panel 100, the first via HL1 does not overlap the second active layer TP2 and the second via HL2 does not overlap the second active layer TP2.

In an embodiment, in the case where the first transistor T1 is in the on state, the carriers in the active layer Tp of the first transistor T1 directionally move between the first source Ts1 and the first drain Td1 of the first transistor T1 so that the current passes between the first source Ts1 of the first transistor T1 and the first drain Td1 of the first transistor T1. Moreover, the directional moving speed of the carriers between the first source Ts1 and the first drain Td1 is related to the strength of the electric field received by the carriers and the mobility of the active layer Tp; therefore, in the thickness direction Z of the display panel 100, the first via HL1 does not overlap the second active layer Tp2 and the second via HL2 does not overlap the second active layer Tp2 so that the first source Ts1 and the first drain Td1 may be connected only to the first active layer Tp1. The second active layer Tp2 is not connected to the first source Ts' and the first drain Td1 so that when the electric field generated in the gate insulating layer 30 between the first active layer Tp1 and the first gate Tg1 acts on the first active layer Tp1 and the second active layer Tp2, the carriers attracted to the surface layer of the channel region of the second active layer Tp2 may enter the first active layer Tp1 from the surface layer of the second active layer Tp2, enabling this part of carriers to move between the first source region and the first drain region in the first active layer Tp1 instead of moving in the second active layer Tp2. Thus, compared with the case where the carriers are transmitted in the second active layer Tp2, the mobility of this part of carriers can be increased, ensuring the carriers to be accurately and quickly transmitted between the first source Ts1 and the first drain Td1, thereby enabling the first transistor T1 to have a faster response speed and higher accuracy and reliability.

Moreover, although the second active layer Tp2 is not connected to the first source Ts1 and the first drain Td1, in the thickness direction of the display panel 100, the second active layer Tp2 overlaps the first gate Tg1, and the overlapping position is the channel region of the second active layer Tp2. In this way, in the case where the first transistor T1 is in the off state, majority carriers in the second active layer Tp2 can also attract the minority carriers of the first active layer Tp1 so that the minority carriers of the first active layer Tp1 cannot reach the surface layer of the first active layer or the number of minority carriers reaching the surface layer of the first active layer can be significantly reduced, thereby enabling the first transistor T1 to have a smaller leakage current in the case where the first transistor T1 is in the off state.

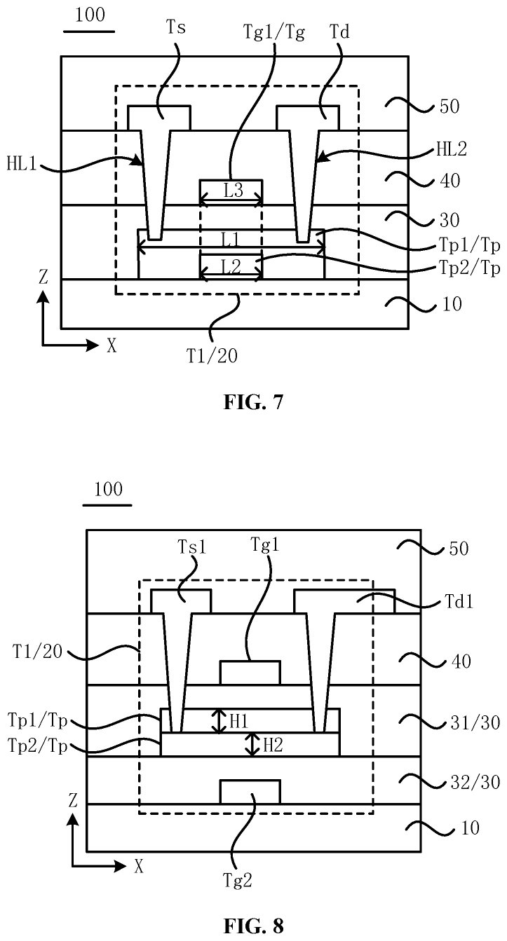

It is to be noted that FIG. 6 is merely an exemplary drawing of the embodiments of the present disclosure. FIG. 6 merely exemplarily illustrates that in the case where in the thickness direction Z of the display panel 100, the first via HL1 does not overlap the second active layer Tp2 and the second via HL2 does not overlap the second active layer Tp2, the dimension L2 of the second active layer Tp2 in the first direction X is larger than the dimension L3 of the first gate Tg1 in the first direction X. In the embodiment of the present disclosure, as shown in FIG. 7, the dimension L2 of the second active layer Tp2 in the first direction X may also be equivalent to the dimension L3 of the first gate Tg1 in the first direction X. In this case, the preceding beneficial effects can also be achieved, and the similarities can be referred to the preceding description, and will not be repeated herein. The dimension L2 of the second active layer Tp2 in the first direction X and the dimension L3 of the first gate Tg1 in the first direction are not specifically limited by the embodiments of the present disclosure.

For ease of description and simplification of the drawings, the solutions in the embodiments of the present disclosure are described below by means of examples in which the dimension of each active layer of the first transistor in the first direction is equivalent.

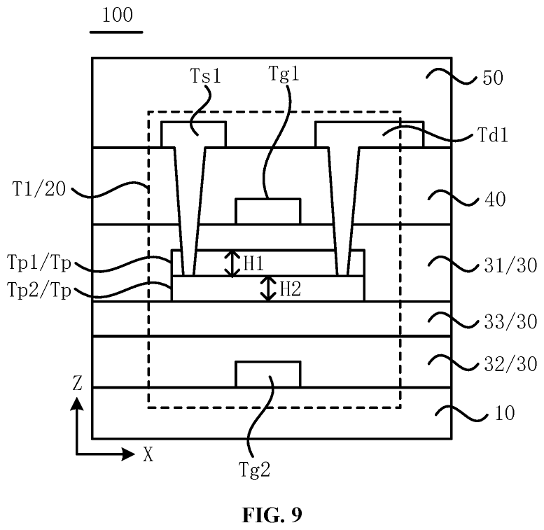

On the basis of the preceding embodiments, optionally, FIG. 8 is a view illustrating the structure of films of another display panel according to an embodiment of the present disclosure. As shown in FIG. 8, the first transistor T1 also includes a second gate Tg2. The second gate Tg2 is located on a side of the second active layer Tp2 facing away from the first active layer Tp1. In this case, a first gate insulating layer 31 may be disposed between the first gate Tg1 and the first active layer Tp1, and a second gate insulating layer 32 may be disposed between the second gate Tg2 and the second active layer Tp1.

In an embodiment, in the case where the first transistor T1 needs to be turned on, corresponding electrical signals may be applied to the first gate Tg1, the second gate Tg2, and the first source Ts1 so that an electric field generated by the first gate insulating layer 31 between the first gate Tg1 and the first active layer Tp1 acts on the first active layer Tp1, and an electric field generated by the second gate insulating layer 32 between the second active layer Tp2 and the second gate Tg acts on the second active layer Tp2. Thus, the first active layer Tp1 and the second active layer Tp2 can contribute carriers at the same time without higher electrical signals. That is, the first transistor T1 can be turned on quickly, thereby enabling the first transistor T1 to have the higher reliability and lower power consumption. In the case where the first transistor T1 is in an off state, the electrical signals generated in the first gate insulating layer 31 and the second gate insulating layer 32 due to applying the electrical signals to the first gate Tg1 and the second gate Tg2 can suppress the carriers to aggregate in the first active layer Tp1 and the second active layer Tp2, thereby enabling the first transistor T1 to have a smaller leakage current in the case where the first transistor T1 is in the off state.

In an embodiment, referring to FIG. 8, in the case where the first gate insulating layer 31 is disposed between the first gate Tg1 and the first active layer Tp1, and the second gate insulating layer 32 is disposed between the second gate Tg2 and the second active layer Tp2, the dielectric constant of the first gate insulating layer 31 may be larger than the dielectric constant of the second gate insulating layer 31.

In an embodiment, the first gate insulating layer 31 having the larger dielectric constant is disposed between the first gate Tg1 and the first active layer Tp1, the defect density at the contact surface between the first active layer Tp1 and the first gate insulating layer 31 can be reduced, and the scattering effect of the contact surface on the carriers can be reduced. When the electric field generated in the first gate insulating layer 31 acts on the first active layer Tp1, the electric field attracts the carriers in the first active layer Tp1 and thus causes part of the carriers to move on the surface layer of the first active layer Tp1 so that when the scattering effect of the contact surface between the first active layer Tp1 and the first gate insulating layer 31 on the carriers is reduced, the carriers attracted to the surface layer of the first active layer Tp1 can maintain a larger mobility, thereby improving the response speed of the first transistor T1. Moreover, since the first active layer Tp1 has the larger mobility, the leakage current can be more easily generated in the first active layer Tp1 in the case where the first transistor T1 is in the off state. When the first gate insulating layer 31 having the larger dielectric constant is subjected to the external electric field, induced charges generated inside the first gate insulating layer 31 can weaken the electric field inside the first gate insulating layer 31, thereby effectively reducing the electric field acting on the first active layer Tp1 of the first gate insulating layer 31 in the case where the first transistor T1 is in the off state, and effectively reducing the leakage current generated due to the larger mobility of the first active layer Tp1. In addition, the dielectric constant of the first gate insulating layer 31 is configured to be larger than the dielectric constant of the second gate insulating layer 32 so that the threshold voltage difference between a transistor composed of the first gate Tg1 and the first active layer Tp1 and a transistor composed of the second gate Tg2 and the second active layer Tp2 due to the mobility difference between the first active layer Tp1 and the second active layer Tp2 can be compensated.

The material of the first gate insulating layer 31 having the larger dielectric constant may include, but is not limited to, at least one of HfO₂, CrO and Al₂O₃, while the material of the second gate insulating layer 32 having the lower dielectric constant may include, but is not limited to, at least one of SiO2 and SiN.

In an embodiment, as shown in FIG. 9, a third gate insulating layer 33 may also be disposed between the second gate insulating layer 32 and the second active layer Tp2. The dielectric constant of the third gate insulating layer 33 may be larger than the dielectric constant of the second gate insulating layer 32.

In an embodiment, the third gate insulating layer 33 is disposed between the second gate insulating layer 32 and the second active layer Tp2, that is, the third gate insulating layer 33 is much closer to the second active layer Tp2, so that the defect density at the contact surface between the second active layer Tp2 and the third gate insulating layer 33 can be reduced by the third gate insulating layer 33 having the larger dielectric constant, and the scattering effect of the contact surface on the carriers can be reduced. When an electric field generated in the third gate insulating layer 33 acts on the second active layer Tp2, the electric field attracts the carriers in the second active layer Tp2 and thus causes part of the carriers to move on the surface layer of the second active layer Tp2 so that when the scattering effect of the contact surface between the second active layer Tp2 and the third gate insulating layer 33 on the carriers is reduced, the carriers attracted to the surface layer of the second active layer Tp2 can maintain a larger mobility, thereby improving the response speed of the first transistor T1. Moreover, the third gate insulating layer 33 having the dielectric constant larger than the dielectric constant of the second gate insulating layer 32 is disposed between the second gate insulating layer 32 and the second active layer Tp2, larger induced charges can be generated inside the third gate insulating layer 33 to weaken the electric field, thereby effectively reducing the electric field acting on the second active layer Tp2 of the third gate insulating layer 33 in the case where the first transistor T1 is in the off state, and enabling the leakage current in the second active layer Tp2 to be smaller and even eliminating the leakage current in the second active layer Tp2.

In the case where the dielectric constant of the first gate insulating layer 31 and the dielectric constant of the third gate insulating layer 33 are both larger than the dielectric constant of the second gate insulating layer 32, the dielectric constant of the third gate insulating layer 33 may be the same as or different from the dielectric constant of the first gate insulating layer 31. In this case, the material of the third gate insulating layer 33 may be the same as or different from the material of the first gate insulating layer 31, and the embodiments of the present disclosure do not specifically limit thereto.

In an embodiment, referring to FIG. 9, the dielectric constant of the third gate insulating layer 33 may be larger than the dielectric constant of the first gate insulating layer 31 to enable the defect density at the contact surface between the second active layer Tp2 having the smaller mobility and the third gate insulating layer 33 to be lower than the defect density at the contact surface between the first active layer Tp1 having the larger mobility and the first gate insulating layer 31 so that the scattering effect of the defect at the contact surface between the second active layer Tp2 and the third gate insulating layer 33 on the carriers is lower than the scattering effect of the defect at the contact surface between the first active layer Tp1 and the first gate insulating layer 31 on the carriers, and thereby the mobility of the second active layer Tp2 can be compensated and the mobility at the surface layer of the second active layer Tp2 can be consistent with the mobility of the first active layer Tp1, thereby further improving the performance of the first transistor T1.

In the case where the first gate insulating layer 31 has a dielectric constant of E1, the second gate insulating layer 32 has a dielectric constant of E2, and the third gate insulating layer 33 has a dielectric constant of E3, E3−E1=E1−E2. In this way, the dielectric constant of E2 of the second gate insulating layer 32, the dielectric constant of E1 of the first gate insulating layer 31, and the dielectric constant of E3 of the third gate insulating layer 33 sequentially increase in an equal difference manner, facilitating controlling the dielectric constant of each gate insulating layer 30 (31, 32 or 33), thereby facilitating simplifying the manufacturing process of the display panel 100 and reducing the manufacturing cost of the display panel 100.

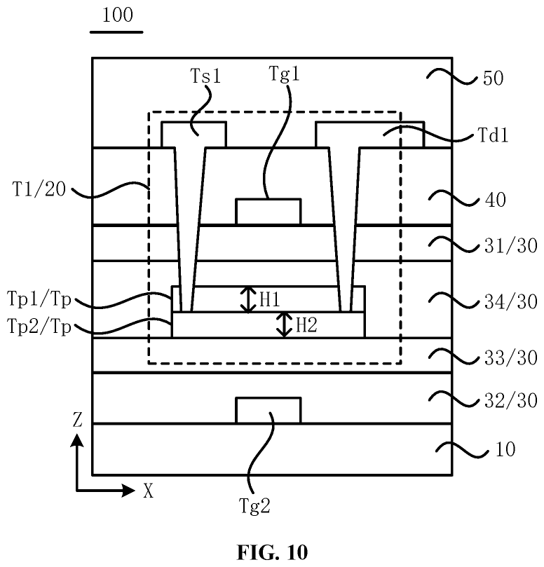

In an embodiment, as shown in FIG. 10, a first gate insulating layer 32 and a fourth gate insulating layer 34 are disposed between the first gate Tg1 and the first active layer Tp1, and the fourth gate insulating layer 34 is located on a side of the first gate insulating layer 32 close to the first active layer. The dielectric constant of the fourth gate insulating layer 34 is larger than the dielectric constant of the first gate insulating layer 32. In this way, the fourth gate insulating layer 34 having the larger dielectric constant is disposed between the first active layer Tp1 and the first gate insulating layer 31, so that a lower defect density can be at the contact surface between the first active layer Tp1 and the fourth gate insulating layer 34, and the scattering effect on the carriers in the first active layer Tp1 can be further reduced, thereby improving the mobility of the first active layer Tp1, enabling the first active layer Tp1 to have the larger mobility, and further improving the performance of the first transistor T1.

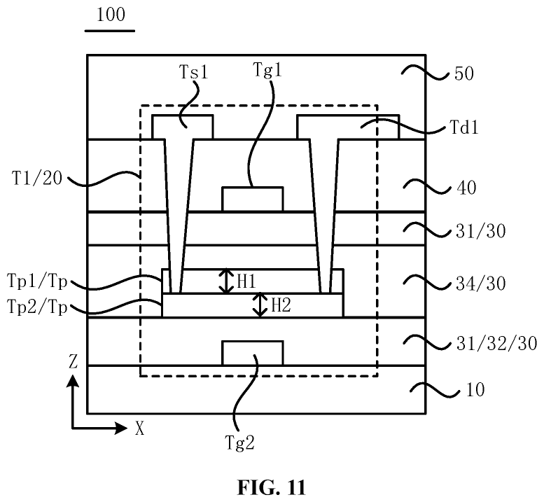

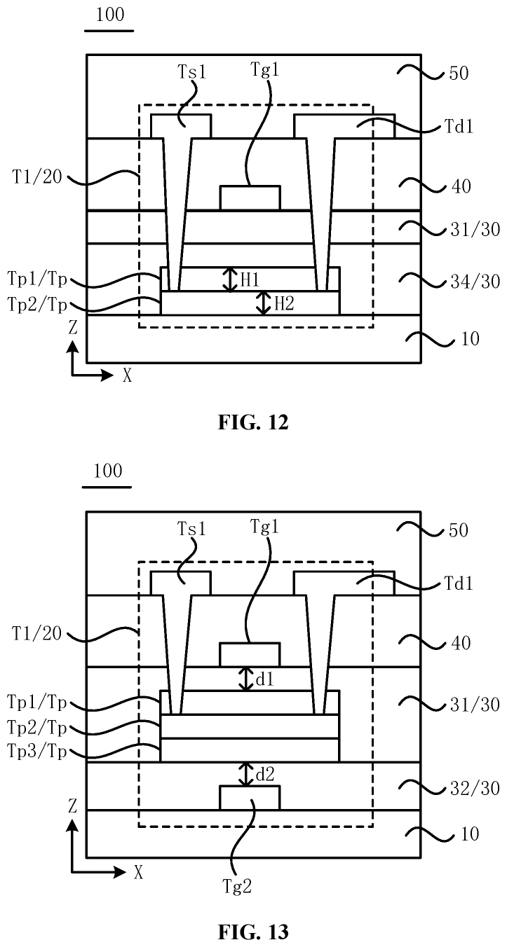

It is to be noted that, FIG. 10 is merely an exemplary drawing of the embodiments of the present disclosure. FIG. 10 merely exemplarily illustrates that in the case where the first transistor T1 includes the first gate Tg1 and the second gate Tg2, two gate insulating layers (i.e., the first gate insulating layer 31 and the fourth gate insulating layer 34) are disposed between the first gate Tg1 and the first active layer Tp1, and two gate insulating layers (i.e., the second gate insulating layer 32 and the third gate insulating layer 33) are also disposed between the second gate Tg2 and the second active layer Tp1. However, in this embodiment of the present disclosure, as shown in FIG. 11, in the case where the first transistor T1 includes the first gate Tg1 and the second gate Tg2, only the second gate insulating layer 32 or the third gate insulating layer 33 may be disposed between the second gate Tg2 and the second active layer Tp1, and both the first gate insulating layer 31 and the fourth gate insulating layer 34 may be disposed between the first gate Tg1 and the first active layer Tp1; or as shown in FIG. 12, in the case where the first transistor T1 includes only the first gate Tg1, both the first gate insulating layer 31 and the fourth gate insulating layer 34 may also be disposed between the first gate Tg1 and the first active layer Tp1, and the embodiments of the present disclosure do not specifically limit thereto.

In an embodiment, referring to any of FIGS. 3 to 12, the thickness H2 of the second active layer Tp2 may be larger than the thickness H1 of the first active layer Tp1. In this way, the second active layer Tp2 having the smaller mobility can contribute more carriers to improve the overall mobility of the first transistor so that the first transistor T1 satisfies the requirements of low power consumption and high reliability.

It can be understood that in the preceding embodiments, the first transistor T1 includes at least two active layers Tp having different mobilities. The first active layer Tp1 and the second active layer Tp2 are merely exemplary descriptions of the active layers Tp in the first transistor T1. Without particular explanation, the first active layer Tp1 and the second active layer Tp2 can represent any two active layers having different mobilities in the first transistor T1. That is, in the embodiments of the present disclosure, the first transistor T1 may include two or more active layers.

In an embodiment, as shown in FIG. 13, the first transistor T1 may also include a third active layer Tp3. The mobility of the third active layer Tp3 is larger than the mobility of the second active layer Tp2. The third active layer Tp3 is located between the second active layer Tp2 and the second gate Tg2.

In an embodiment, in the case where the third active layer Tp3 is located between the second active layer Tp2 and the second gate Tg2, the third active layer Tp3 close to the second gate Tg2 is also the active layer having the larger mobility so that a source region and a drain region in the third active layer Tp3 can be turned on through a channel region of the third active layer Tp3 by applying a smaller electric signal to the second gate Tg2 on the premise that the electric signals applied to the first source Ts1 maintain unchanged, thereby enabling the first transistor T1 to have the lower power consumption and higher reliability. Moreover, in the case where the third active layer T3 is located between the second active layer Tp2 and the second gate Tg2, the second active layer Tp2 is located between the third active layer Tp3 and the first active layer Tp1, and thereby in the case where the first transistor T1 is in the off state, the second active layer Tp2 suppresses both the leakage current in the first active layer Tp1 and the leakage current in the third active layer Tp3, further enabling the first transistor T1 to have a lower leakage current in the case where the first transistor T1 is in the off state.

It is to be noted that the mobility of the first active layer Tp1 and the mobility of the third active layer Tp3 are both larger than the mobility of the second active layer Tp2; and the mobility of the first active layer Tp1 may be larger than or equal to the mobility of the third active layer Tp3, or the mobility of the first active layer Tp1 may be smaller than the mobility of the third active layer Tp3, and the embodiments of the present disclosure do not specifically limit thereto. In an embodiment, the mobility of the third active layer Tp3 may be considered to be equivalent to the mobility of the first active layer Tp1.

In an embodiment, referring to FIG. 13, in the case where the third active layer Tp3 is located between the second active layer Tp2 and the second gate Tg2, the second gate insulating layer 32 is located between the third active layer Tp3 and the second gate Tg2. In this case, the thickness d1 of the second gate insulating layer 32 may be larger than the thickness d2 of the first gate insulating layer 31.

In an embodiment, the first gate Tg1 and the first active layer Tp1 may compose a first parasitic capacitor C1 of the first transistor T1. In this case, the first gate Tg1 and the first active layer Tp1 are one plate and another plate of the first parasitic capacitor C1 respectively. The first gate insulating layer 31 may be used as a dielectric layer of the first parasitic capacitor C1. The second gate Tg2 and the second active layer Tp2 may compose a second parasitic capacitor C2 of the first transistor T1. In this case, the second gate Tg2 and the second active layer Tp2 are one plate and another plate of the second parasitic capacitor C2 respectively. The second gate insulating layer 32 may be used as a dielectric layer of the second parasitic capacitor C2. The capacitance C=ES/d, S denotes an overlap area of the two plates of the capacitor, E denotes the dielectric constant of the dielectric layer of the capacitor, and D denotes the distance between the two plates of the capacitor, that is, on the premise that the overlap area between the two plates of the capacitor maintains unchanged, the capacitance increases as the dielectric constant of the dielectric layer between the two plates increases and decreases as the distance between the two plates increases. Therefore, in the case where the dielectric constant of the first gate insulating layer 31 may be larger than the dielectric constant of the second gate insulating layer 31, the thickness d1 of the second gate insulating layer 32 may be configured to be larger than the thickness d2 of the first gate insulating layer 31, thereby reducing the difference between the first parasitic capacitor C1 and the second parasitic capacitor C2, enabling the transistors on two sides of the second active layer Tp2 in the first transistor T1 to have the consistent performance, and further improving the reliability and stability of the first transistor T1.

In an embodiment, referring to FIG. 13, the first gate insulating layer 31 has a dielectric constant of E1 and a thickness of d1, and the first gate Tg1 has a vertical projection area of S1 on the first gate insulating layer 31; and the second gate insulating layer Tg2 has a dielectric constant of E2 and a thickness of d2, and the second gate Tg2 has a vertical projection area of S2 on the second gate insulating layer 32, and E1*S1/d1=E2*S2/d2. The first parasitic capacitor C1 composed of the first gate Tg1 and the first active layer Tp1 is consistent with the second parasitic capacitor C2 composed of the second gate Tg2 and the second active layer Tp2, thereby further improving the reliability and stability of the first transistor T1.

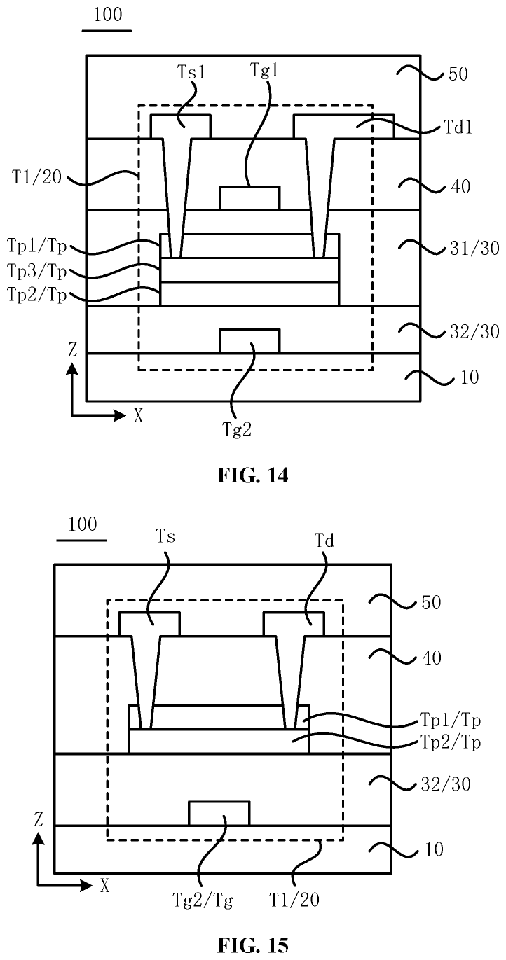

In an embodiment, as shown in FIG. 14, in the case where the first transistor T1 includes a third active layer Tp3. The third active layer Tp3 may also be located between the first active layer Tp1 and the second active layer Tp2. In this case, the mobility of the third active layer Tp3 may be smaller than the mobility of the first active layer Tp1, and the mobility of the third active layer Tp3 may be larger than the mobility of the second active layer Tp2. In this way, in the thickness direction Z of the display panel 100, mobilities of various active layers Tp are laminated in the first transistor T1 sequentially increase, thereby enabling the smooth transition of the moving speed of carriers in each active layer Tp of the first transistor T1, and further improving the reliability and stability of the first transistor T1.

In the preceding embodiments, the first transistor T1 includes at least the first gate Tg1 located on a side of the first active layer Tp1 facing away from the second active layer Tp2. In this embodiment of the present disclosure, as shown in FIG. 15, the first transistor T1 may also not include the first gate on a side of the first active layer Tp1 facing away from the second active layer Tp2, and include only the second gate Tg2 located on a side of the second active layer Tp2 facing away from the first active layer Tp1. In this case, the first transistor T1 can have a smaller leakage current in the case where the first transistor T1 is in the off state, thereby enabling the first transistor T1 to be adapted to the switching transistor in the pixel circuit 20. That is, the second gate Tg1 of the first transistor T1 may be configured to receive a scanning signal so that the first transistor Tg1 can be turned on or turned off under the control of the scanning signal.

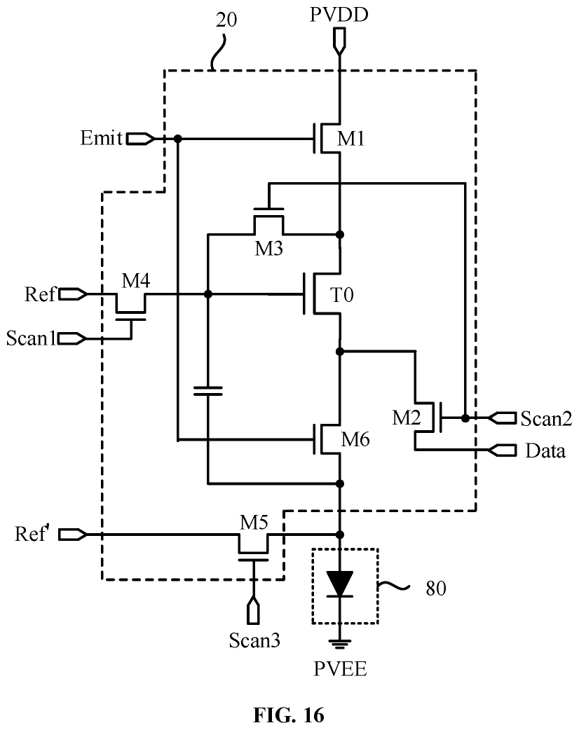

In an embodiment, the case where the display unit in the display panel is a light-emitting element driven by a current mode is used as an example. FIG. 16 is a view illustrating the structure of a pixel circuit according to an embodiment of the present disclosure. As shown in FIG. 16, the pixel circuit 20 is a common 7T1C (i.e., including seven transistors M1, M2, M3, M4, M5, M6 and T0, and one storage capacitor Cst) circuit. In the seven transistors of the pixel circuit 10, the transistors M1, M2, M3, M4, M5 and M6 are turned on or turned off under the control corresponding scanning signals (Scan1, Scan2, Scan3 and Emit) to control on or off of transmission paths of a data signal Data, an initialization signal Ref, and a reset signal Ref and to control a driving current provided to a light-emitting element 80. The transistor T0 converts the data signal Data into the driving current capable of driving the light-emitting element 80 to emit light. The reset signal Ref may be the same as or different from the initialization signal Ref, and the embodiments of the present disclosure do not specifically limit thereto. It can be understood that in the case where the pixel circuit 20 provided by the embodiments of the present disclosure is the 7T1C circuit, the driving timing of the pixel circuit 20 may be similar to the driving timing of the 7T1C circuit well known to those skilled in the art, and will not be repeated herein.

Referring to FIGS. 15 and 16, since the transistors M1, M2, M3, M4, M5 and M6 are turned on or turned off under the control the corresponding scanning signals (Scan1, Scan2, Scan3 and Emit), at least part of the transistors M1, M2, M3, M4, M5 and M6 may be the first transistor T1. In an embodiment, the transistor M3 and the transistor M4 are directly electrically connected to a gate of the transistor T0 and each of the transistor M3 and the transistor M4 is the first transistor in the pixel circuit 20 so that the transistor M3 and the transistor M4 may have a smaller leakage current when the transistor T0 provides the driving current for the light-emitting element 80 according to a potential of the gate of the transistor T0, thereby enabling the potential of the gate of the transistor T0 to maintain stable. That is, the transistor T0 can provide a stable driving current to the light-emitting element 80, further enabling the light-emitting element 80 to stably emit the light and improving the display effect of the display panel 100.

It is to be noted that the above merely exemplarily illustrates the case where the transistor M3 and the transistor M4 are directly electrically connected to the transistor T0 for providing the driving current and each of the transistor M3 and the transistor M4 is the first transistor in the pixel circuit 20 as shown in FIG. 16, and in the embodiments of the present disclosure, the other transistors (M1, M2, M5 and M6) in the pixel circuit 20 may also be the first transistor T1. The type of the other transistors can be designed as needed, and the embodiments of the present disclosure do not specifically limit thereto.

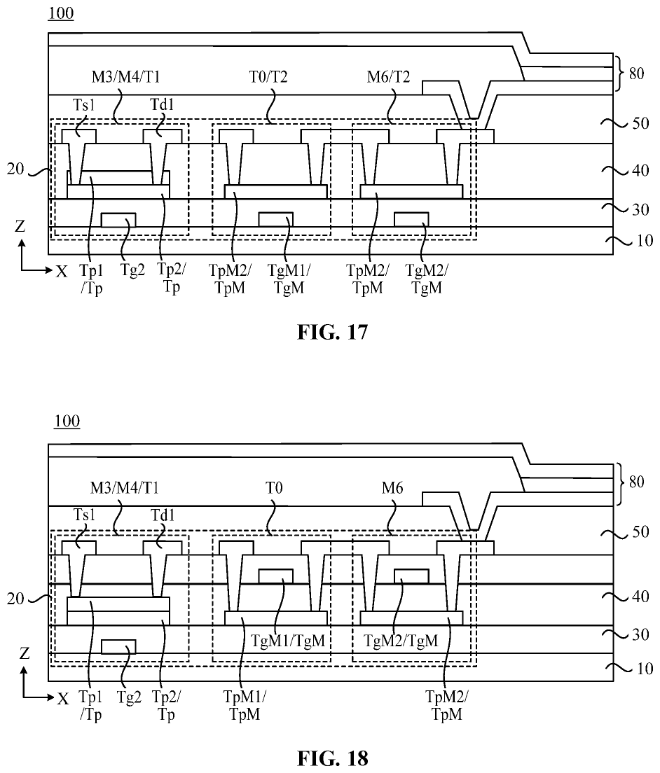

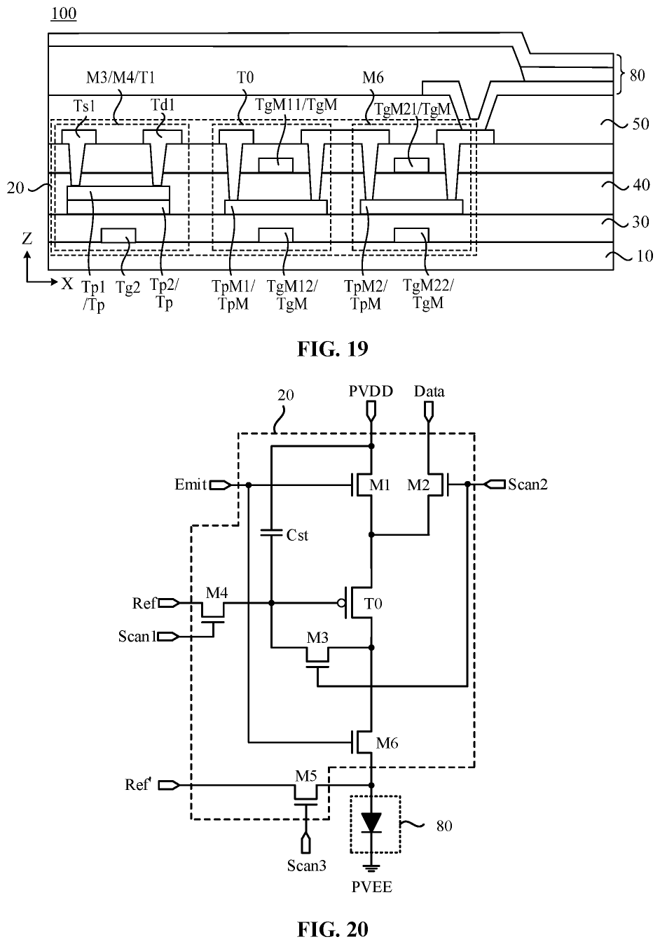

The case where the transistor M3 and the transistor M4 are directly electrically connected to the transistor T0 for providing the driving current and each of the transistor M3 and the transistor M4 is the first transistor in the pixel circuit 20 is used as an example. FIG. 17 is a view illustrating the structure of films of another display panel according to an embodiment of the present disclosure. Referring to FIGS. 16 and 17, active layers TpM (TpM1 and TpM2) of the transistors T0, M1, M2, M5 and M6 may be disposed in the same layer as the first active layer Tp1 or the second active layer Tp2 of the first transistor T1, and gates TgM (TgM1 and TgM2) of the transistors T0, M1, M2, M5 and M6 may also be disposed in the same layer as the second gate Tg2 of the first transistor T1. Alternatively, referring to FIGS. 16 and 18, the gates TgM (TgM1 and TgM2) of the transistors T0, M1, M2, M5 and M6 may not be disposed in the same layer as the second gate Tg2 of the first transistor T1, and in this case, the gates TgM (TgM1 and TgM2) of the transistors T0, M1, M2, M5 and M6 may be located on a side of the active layers TpM (TpM1 and TpM2) of the transistors T0, M1, M2, M5 and M6 facing away from the second gate Tg2. Alternatively, referring to FIGS. 16 and 19, the transistors T0, M1, M2, M5 and M6 may include gates TgM (TgM12, TgM22) disposed in the same layer as the second gate Tg2 of the first transistor T1, or may include gates TgM (TgM11, TgM21) not disposed in the same layer as the second gate Tg2 of the first transistor T1. In this case, the transistors M1, M2, M5 and M6 are double-gate transistors.

In the preceding embodiments, the active layer of the transistor T0 for providing the driving current is disposed in the same layer as the first active layer Tp1 or the second active layer Tp2 of the first transistor T1. In this case, the channel type of the transistor T0 is the same as the channel type of the first transistor T1. For example, in the case where the channel type of the first transistor T1 is N-type, the channel type of the transistor T0 is also N-type so that a first electrode of the transistor T0 is electrically connected to a signal terminal providing a positive power supply signal PVDD through the transistor M1, the first electrode of the transistor T0 is also electrically connected to the gate of the transistor T0 through the transistor M3, a second electrode of the transistor T0 is electrically connected to the light-emitting element 80 through the transistor M6, and the second electrode of the transistor T0 is also electrically connected to a signal terminal providing the data signal Data through the transistor M2. It can be understood that the transistor T0 of P-type and the first transistor T1 of P-type have the similar connection mode as the transistor T0 of N-type.

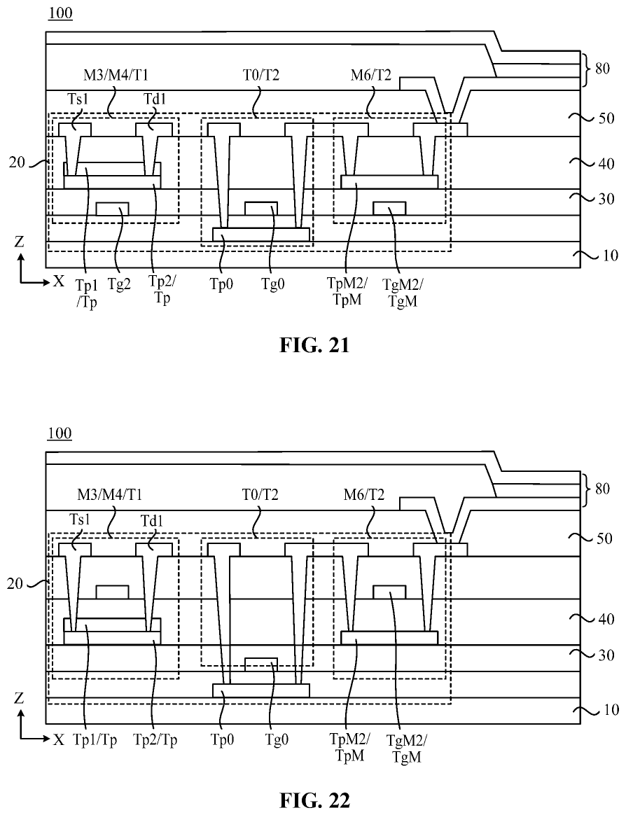

In an embodiment, the type of the transistor for providing the driving current to the light-emitting element in the pixel circuit may also be different from the type of the first transistor. Referring to FIGS. 20 and 21, the case where the transistor M3 and the transistor M4 are directly electrically connected to the transistor T0 for providing the driving current and each of the transistor M3 and the transistor M4 is the first transistor in the pixel circuit 20 is also used an example. In the case where the channel type of the first transistor T1 is N-type and the channel type of the transistor T0 is P-type, a first electrode of the transistor T0 is electrically connected to the signal terminal providing the positive power supply signal PVDD through the transistor M1, the first electrode of the transistor T0 is also electrically connected to the signal terminal providing the data signal Data through the transistor M2, a second electrode of the transistor T0 is electrically connected to the light-emitting element 80 through the transistor M6, and the second electrode of the transistor T0 is also electrically connected to a gate of the transistor T0 through the transistor M3. In this case, an active layer Tp0 of the transistor T0 may be located on a side of the first active layer Tp1 and the second active layer Tp2 of the first transistor T1 close to the substrate 10 and a gate Tg0 of the transistor T0 may be located on a side of the active layer Tp0 facing away from the substrate 10 so that the gate Tg0 of the transistor T0 may be disposed in the same layer as the second gate Tg2 of the first transistor T1.

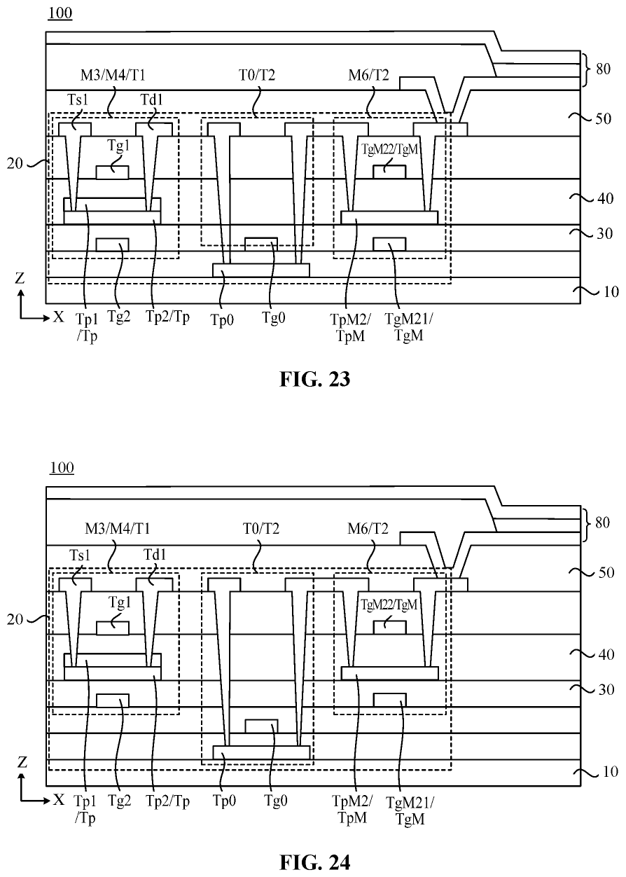

In other embodiments of the embodiments of the present disclosure, referring to FIGS. 20 and 22, the first transistor T1 may also include only the first gate Tg1. In this case, the gate Tg0 of the transistor T0 is located on a side of the active layer Tp0 facing away from the substrate 10, the first active layer Tp1 and the second active layer Tp2 are both located on a side of the gate Tg0 of the transistor T0 facing away from the substrate 10, and the first gate Tg1 is located on a side of the first active layer Tp1 facing away from the substrate 10. Alternatively, referring to FIGS. 20 and 23, in the case where the first transistor T1 includes both the first gate Tg1 and the second gate Tg2, the gate Tg0 of the transistor T0 may be disposed in the same layer as the second gate Tg2 of the first transistor T1. Alternatively, referring to FIGS. 20 and 24, in the case where the first transistor T1 includes at least the second gate Tg2, the gate Tg0 of the transistor T0 may also be located on a side of the second gate Tg2 of the first transistor T1 close to the substrate 10.

It is to be noted that in the case where the channel type of the first transistor T1 is different from the channel type of the transistor T0 for providing the driving current, as shown in FIGS. 21 to 24, the active layers TPM of the other transistors (M1, M2, M5 and M6) in the pixel circuit 20 in addition to the first transistor T1 and the transistor T0 may be disposed in the same layer as the first active layer Tp1 or the second active layer Tp2 of the first transistor T1. The gates TgM of the other transistors (M1, M2, M5 and M6) may be disposed in the same layer as the first gate Tg1 and/or the second gate Tg2 of the first transistor T1 such that the channel type of the other transistors (M1, M2, M5 and M6) is the same as the channel type of the first transistor T1. Alternatively, in other embodiments, the channel type of the transistors in addition to the first transistor and the transistor for providing the driving current may be the same as the channel type of the transistor for providing the driving current so that the active layers of the other transistors are disposed in the same layer as the active layer of the transistor for providing the driving current. On the premise of satisfying the core inventive points of the embodiments of the present disclosure, the embodiments of the present disclosure do not specifically limit thereto.

For ease of description, without particular explanation, the solutions of the embodiments of the present disclosure will be described below by means of examples in which all transistors in the pixel circuit have the same channel type.

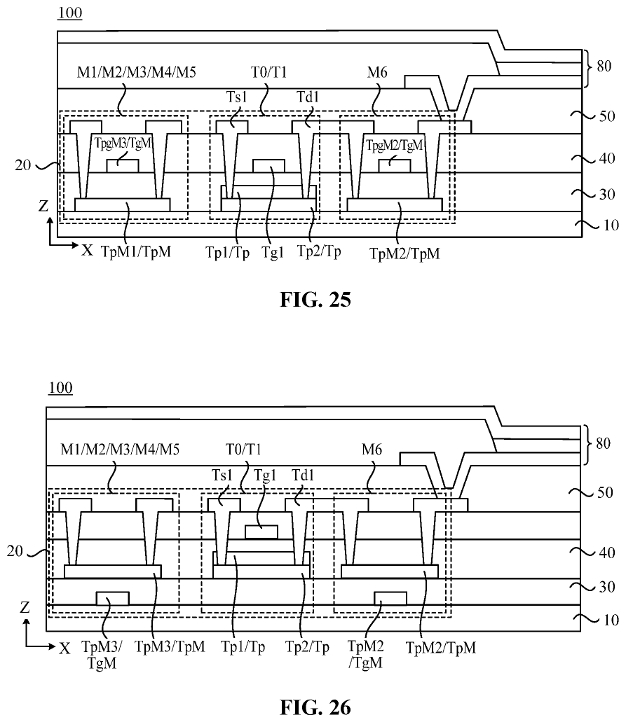

In an embodiment, as shown in FIG. 25, FIG. 25 is a view illustrating the structure of films of another display panel according to an embodiment of the present disclosure. In the case where the first transistor T1 includes at least a first gate Tg14, if the display panel also includes multiple light-emitting elements 80 located on a side of the substrate and pixel circuits 20 are electrically connected to the light-emitting elements 80, the first gate Tg1 of the first transistor T1 may also be configured to receive a data signal so that the first transistor T1 can provide a driving current for the light-emitting elements 80 according to the data signal.

In an embodiment, the case where the pixel circuit 20 is the pixel circuit shown in FIG. 16 is used as an example. Referring to FIGS. 25 and 16, in the case where the first transistor T1 includes the first gate Tg1, the first gate Tg1 is located on a side of the first active layer Tp1 facing away from the second active layer Tp2, when the electric field generated in the first gate insulating layer 31 between the first gate Tg1 and the first active layer Tp1 has a smaller intensity, the channel region in the first active layer Tp1 can be ensured to communicate with the source region and the drain region in the first active layer Tp1. That is, the first source Ts1 and the first drain Td1 are turned on to generate the driving current, thereby enabling the first transistor to be characterized by low power consumption and high reliability, thereby enabling the driving current matching the luminance required by the light-emitting element 80 to be generated between the first source Ts1 and the first drain Td1 of the first transistor T1 to enable the light-emitting element 80 to accurately emits light as long as a smaller data signal is provided for the first gate Tg1 when the first transistor is used as the driving transistor for driving the light-emitting element 80 to emit the light. Moreover, since the luminance requirement of the light-emitting element 80 can be satisfied as long as a smaller data signal is provided for the first gate Tg1 of the first transistor T1, the light-emitting element 80 varies within a large display luminance range as long as the data signal provided for the first gate Tg1 varies within a smaller range. For example, when the display luminance level of the light-emitting element 80 is represented by a gray scale of 0 to 255, the data signal varies within a smaller range, and the display luminance of the light-emitting element 80 varies in the gray scale of 0 to 255, thereby facilitating the low power consumption of the display panel 100.

It is to be noted that, in the embodiments of the present disclosure, the first transistor T1 can generate a smaller driving current when a smaller data signal is provided for the first gate Tg1, and the first transistor T1 can generate a larger driving current when a larger data signal is provided for the first gate Tg1. That is, in the case where the first transistor T1 is a N-type transistor, the smaller data signal has a smaller voltage value. In the case where the first transistor T1 is a P-type transistor, the smaller data signal is a data signal having a larger voltage value. The specific type of the first transistor T1 is not limited by the embodiments of the present disclosure.

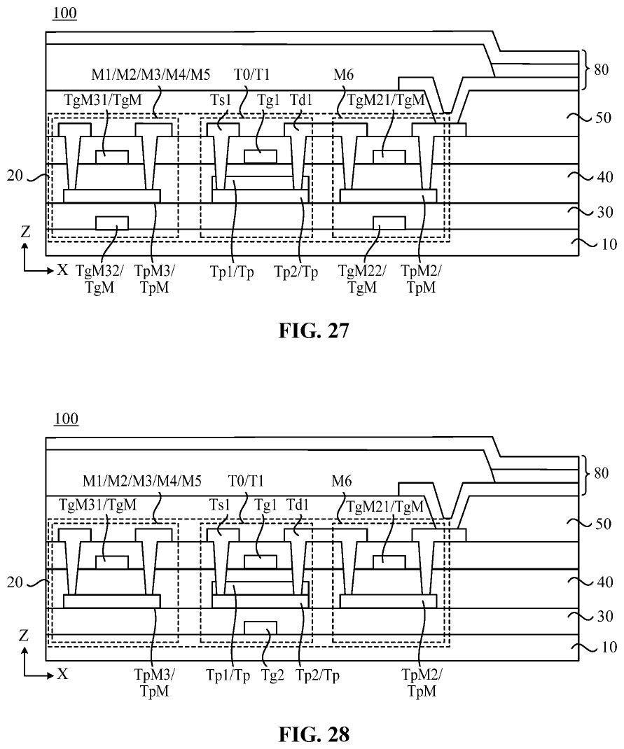

It can be understood that, referring to FIGS. 16 and 25, in the case where the first transistor T1 is the driving transistor T0 receiving the data signal and providing the driving current for the light-emitting element 80, the active layers TpM (TpM2 and TpM3) of the other transistors M1, M2, M3, M4, M5 and M6 in the pixel circuit 20 may be disposed in the same layer as the first active layer Tp1 or the second active layer Tp2 of the first transistor T1, and the gates TgM (TgM2 and TgM3) of the transistors M1, M2, M3, M4, M5 and M6 may also be disposed in the same layer as the first gate Tg1 of the first transistor T1. Alternatively, referring to FIGS. 16 and 26, the gates TgM (TgM2 and TgM3) of the transistors M1, M2, M3, M4, M5 and M6 may not be disposed in the same layer as the first gate Tg1 of the first transistor T1. In this case, the gates TgM (TgM2 and TgM3) of the transistors M1, M2, M3, M4, M5 and M6 may be located on a side of the active layers TpM (TpM2 and TpM3) of the transistors M1, M2, M3, M4, M5 and M6 facing away from the first gate Tg1. Alternatively, referring to FIGS. 16 and 27, the transistors M1, M2, M3, M4, M5 and M6 may include gates TgM (TgM21 and TgM31) disposed in the same layer as the first gate Tg1 of the first transistor T1, or may include gates TgM (TgM22 and TgM32) not disposed in the same layer as the first gate Tg1 of the first transistor T1. In this case, the transistors M1, M2, M3, M4, M5 and M6 are double-gate transistors.

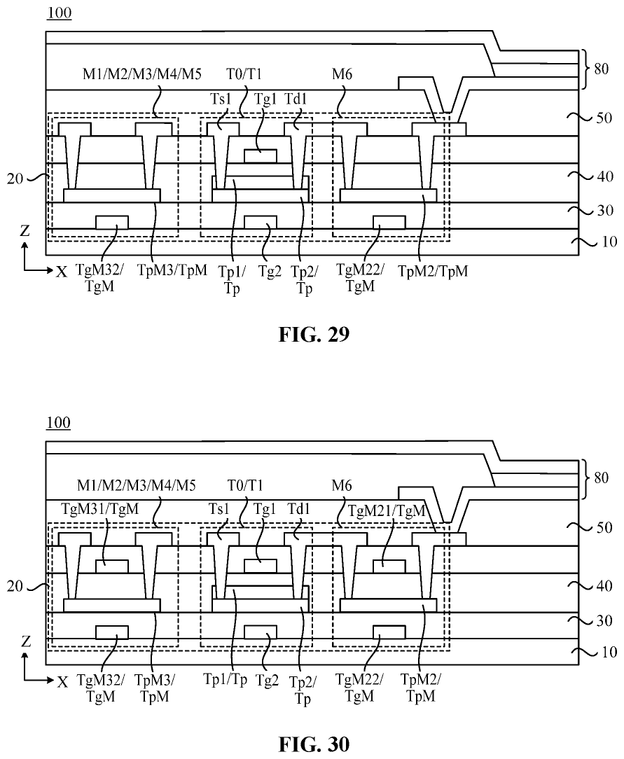

It can be understood that, referring to FIG. 28, in the case where the first transistor T1 includes both the first gate Tg1 and the second gate Tg2, and may also be used as the driving transistor T0 providing the driving current for the light-emitting element 80, in this case, the active layers TpM (TpM2 and TpM3) of the other transistors M1, M2, M3, M4, M5 and M6 may also be disposed in the same layer as the first active layer Tp1 or the second active layer Tp2 of the first transistor T1, and the gates TgM (TgM2 and TgM3) of the transistors M1, M2, M3, M4, M5 and M6 may also be disposed in the same layer as the first gate Tg1 of the first transistor T1. Alternatively, referring to FIG. 29, the gates TgM (TgM2 and TgM3) of the transistors M1, M2, M3, M4, M5 and M6 may also be disposed in the same layer as the second gate Tg2 of the first transistor T1. Alternatively, referring to FIG. 30, the transistors M1, M2, M3, M4, M5 and M6 may include the gates TgM (TgM21 and TgM31) disposed in the same layer as the first gate Tg1 of the first transistor T1, and may also include the gates TgM (TgM22 and TgM32) disposed in the same layer as the second gate Tg2 of the first transistor T1. In this case, the transistors M1, M2, M3, M4, M5 and M6 are double-gate transistors.

For ease of description, the solutions in the embodiments of the present disclosure are described below by means of examples in which the first transistor T1 includes both the first gate Tg1 and the second gate Tg2, and the other transistors include the transistors disposed in the same layer as the first gate Tg1.

It can be understood that, in the embodiments of the present disclosure, each of at least part of the pixel circuits of the display panel includes the first transistor. That is, the pixel circuits including the first transistor may be all of the pixel circuits in the display panel or part of the pixel circuits in the display panel, and the embodiments of the present disclosure do not specifically limit thereto. In an embodiment, the pixel circuits including the first transistor may be a first pixel circuit. The other transistors in the first pixel circuit may be a second transistor. The second transistor includes a fourth active layer. The fourth active layer of the second transistor may be disposed in the same layer as the first active layer or the second active layer of the first transistor so that a corresponding film does not need to be disposed additionally in the display panel for disposing the active layer of the second transistor, thereby facilitating simplifying the structure of the display panel, simplifying the manufacturing process of the display panel, and further facilitating the lightweight and low cost of the display panel.

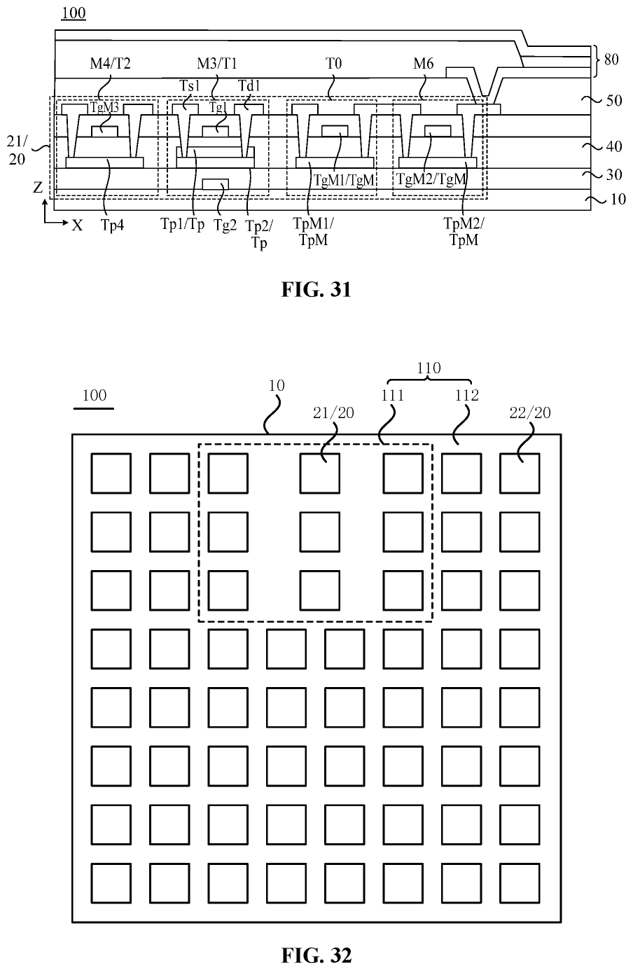

In an embodiment, FIG. 31 is a view illustrating the structure of films of another display panel according to an embodiment of the present disclosure. As shown in FIG. 31, a first pixel circuit 21 also includes a driving transistor T0. In the same first pixel circuit 21, a second transistor T2 is configured to transmit a reset signal to the driving transistor T0 to reset the driving transistor T0. A first transistor T1 is configured to transmit a compensation signal to the driving transistor T0 to perform a threshold compensation on the driving transistor T0.

In an embodiment, the pixel circuit shown in FIG. 16 is used as an example. Referring to FIGS. 31 and 16, In the case where the second transistor T2 is configured to transmit the reset signal to the driving transistor T0 to reset the driving transistor T0, the transistor M4 is the second transistor T2. One of a source and a drain in the second transistor T2 receives the reset signal Ref, and the other one of the source and the drain in the second transistor T2 is electrically connected to a gate of the driving transistor T0. A gate of the second transistor T2 receives the scanning signal Scant. When the scanning signal Scant controls the second transistor T2 to be turned on, the second transistor T2 may transmit the reset signal Ref to the gate of the drive transistor T0 to reset the drive transistor T0, preventing the signal written to the gate of the drive transistor T0 in the previous display period from affecting the data signal Data written to the gate of the drive transistor T0 in the current display period. In the case where the first transistor T1 is configured to transmit the compensation signal to the driving transistor T0 to perform the threshold compensation on the driving transistor T0, the transistor M3 is the first transistor T1. One of the first source Ts1 and the first drain Td1 of the first transistor T1 is electrically connected to the source or the drain of the driving transistor, and the other one of the first source Ts' and the first drain Td1 of the first transistor T1 is electrically connected to the gate of the driving crystal T0. The first gate Tg1 and the second gate Tg2 of the first transistor T1 receive the same scanning signal Scan2 as a gate of the transistor M2. In this case, in the case where the scanning signal Scan2 controls both the first transistor T1 and the transistor M2 to be turned on, the data signal Data can be transmitted to the gate of the driving transistor T0 sequentially through the transistor M2, the driving transistor T0, and the first transistor T1 until a gate signal of the driving transistor T0 is a sum of a voltage Vdata of the data signal Data and a threshold voltage Vth0 of the driving transistor T0, the driving transistor T0 is in a critical state of being turned off, and no signal is written to the gate of the driving transistor T0, thereby achieving the compensation for the threshold voltage Vth0 of the driving transistor T0 while the data signal Data is written.

In this way, in the case where the scanning signal Scan2 controls the first transistor T1 to be turned off, the first transistor T1 can have a smaller leakage current. On the one hand, the effect of the leakage current of the first transistor T1 on the potential of the gate of the driving transistor T0 can be reduced. On the other hand, when the leakage current of the first transistor T1 decreases, the potential of the gate of the driving transistor T0 cannot be increased due to the leakage of the first transistor T1, avoiding that the current path from the gate of the driving transistor T0 to a signal terminal providing the reset signal Ref is formed due to the high potential of the gate of the driving transistor T0 so that the signal is recharged to the signal terminal providing the reset signal Ref and thus the signal terminal providing the reset signal Ref is damaged.

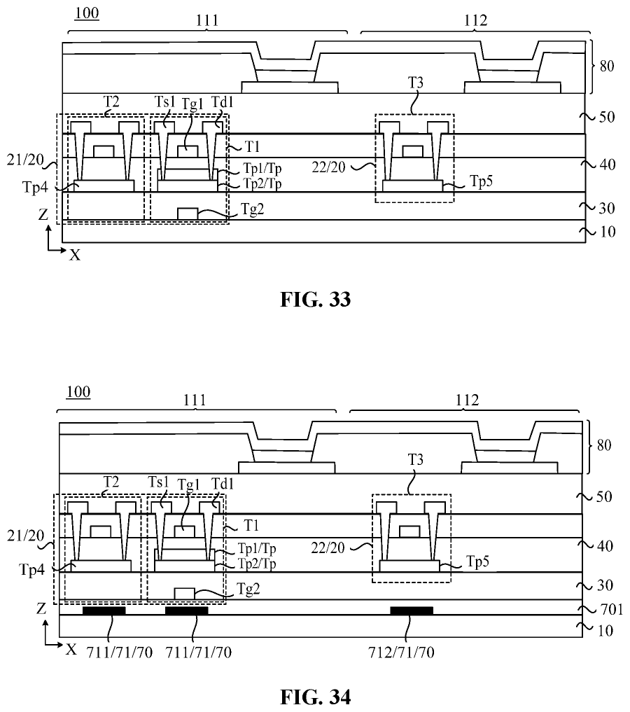

In an embodiment, FIG. 32 is a top view of another display panel according to an embodiment of the present disclosure. FIG. 33 is a view illustrating the structure of films of another display panel according to an embodiment of the present disclosure. Referring to FIGS. 32 and 33, a display region 100 of a display panel 100 may include a first display region 111 and a second display region 112. The light transmittance of the second display region 112 is smaller than the light transmittance of the first display region 111. The second display region 112 at least partially surrounds the first display region 111. In this case, the display panel 100 also includes second pixel circuits 22. The second display region 112 includes the second pixel circuits 22 and the first display region 111 includes first pixel circuits 21. That is, each of the first pixel circuits located in the first display region 111 includes a first transistor T1, and each of the second pixel circuits 22 located in the second display region 112 includes a third transistor T3. The third transistor T3 includes a fifth active layer Tp5. The fifth active layer Tp5 is disposed in the same layer as a second active layer Tp2 or a first active layer Tp1.

The first display region 111 has a larger light transmittance so that the first display region 111 can be used as an optical sensor disposition region for disposing an optical sensor. The optical sensor may include a camera, an optical fingerprint recognition sensor and the like. Meanwhile, since the first display region 111 has a larger light transmittance, the density of the first pixel circuits 21 in the first display region 111 is smaller than the density of the second pixel circuits 22 in the second display region 112; and/or the dimension of the first pixel circuit 21 in the first display region 111 is smaller than the dimension of the second pixel circuit 22 in the second display region 112. Correspondingly, the number of light-emitting elements 80 for illuminance in the first display region 111 is also smaller than the number of light-emitting elements 80 for illuminance in the second display region 112; and/or the dimension of a light-emitting element 80 for illuminance in the first display region 111 is also smaller than the dimension of a light-emitting element 80 for illuminance in the second display region 112. In this case, the first pixel circuit 21 in the first display region 111 includes the first transistor T1, the light-emitting element 80 has a stable and accurate display illuminance when the first transistor T1 controls the light-emitting element 80 electrically connected to the first transistor T1 in the first display region 111, thereby compensating the display difference caused by different setting manners of the light-emitting elements 80 and the pixel circuits 20 in the first display region 111 and the second display region 112, thereby further improving the display uniformity of the display panel 100.

It can be understood that in the case where a fourth active layer Tp4 of a second transistor T2 of the first pixel circuit 21 is disposed on the same layer as the first active layer Tp1 or the second active layer Tp2 of the first transistor T1 of the first pixel circuit 21, and the fifth active layer Tp5 of the third transistor T3 of the second pixel circuit 22 is disposed on the same layer as the first active layer Tp1 or the second active layer Tp2 of the first transistor T1, both the fifth active layer Tp5 of the third transistor T3 and the fourth active layer Tp4 of the second transistor T2 may be disposed in the same layer as the first active layer Tp1, or both the fifth active layer Tp5 of the third transistor T3 and the fourth active layer Tp4 of the second transistor T2 may also be disposed in the same layer as the second active layer Tp2. In this case, the fifth active layer Tp5 and the fourth active layer Tp4 are disposed in a same layer and are made of a same material. Alternatively, in an embodiment, one of the fifth active layer Tp5 and the fourth active layer Tp4 is disposed in the same layer as the first active layer Tp1, and the other one of the fifth active layer Tp5 and the fourth active layer Tp4 is disposed in the same layer as the second active layer Tp2. No matter in which manner the fifth active layer Tp5 and the fourth active layer Tp4 are set, the structure and the manufacturing process of the display panel 100 can be simplified, facilitating the lightweight and low cost of the display panel 100.

In an embodiment, as shown in FIG. 34, a corresponding light shielding layer 70 may also be disposed between the first transistor T1 and the substrate 10. In a thickness direction of the display panel 100, light shielding structures 71 of light shielding layers 70 overlap the active layers (Tp1, Tp2, Tp4 and Tp5) of the transistors (T1, T2 and T3). In a preferred embodiment, in a thickness direction Z of the display panel 100, the light shielding structures 71 of the light shielding layers 70 cover at least channel regions of the active layers (Tp1, Tp2, Tp4 and Tp5) in the transistors (T1, T2 and T3) to block light incident from the substrate 10 side, preventing the light from entering the active layers (Tp1, Tp2, Tp4 and Tp5) and affecting the active layers (Tp1, Tp2, Tp4 and Tp5), thereby improving the stability and reliability of the transistors (T1, T2 and T3).

It is to be noted that if the light shielding layer 70 is a film having the conductive function, a corresponding insulating layer 701 also needs to be disposed between the light shielding layer 70 and the first transistor T1. In the case where the light shielding layer 70 does not have the conductive function, a corresponding insulating layer 701 may be disposed between the light shielding layer 70 and the first transistor T1 or may not be disposed between the light shielding layer 70 and the first transistor T1, and the embodiments of the present disclosure do not specifically limit thereto.

In an embodiment, referring to FIGS. 32 and 34, in the case where the display region 110 of the display panel 100 includes the first display region 111 and the second display region 112, the second display region 112 at least partially surrounds the first display region 111, and the light transmittance of the second display region 112 is less than the light transmittance of the first display region. Each of light shielding structures 711 located in the first display region 111 may be connected to a first potential, and a light shielding structure 712 located in the second display region 112 may be connected to a second potential. The second potential is larger than the first potential.

In an embodiment, the structure of the pixel circuit shown in FIG. 16 is used as an example. Referring to FIGS. 16, 32 and 34, in the case where the light shielding structure 711 located in the first display region 111 is connected to the first potential, the potential connected to the light shielding structure 711 in the first display region 111 may be a negative power supply signal PVEE so that a signal line for transmitting the negative power supply signal PVEE may include the light shielding structure 711, thereby reducing the transmission impedance of the negative power supply signal during the transmission. In the case where the light shielding structure 712 in the second display region 112 is connected to the second potential, the potential connected to the light shielding structure 712 in the second display region 112 may be a positive power supply signal PVDD so that a signal line for transmitting the positive power signal PVDD may include the light shielding structure 712, thereby reducing the transmission impedance of the positive power supply signal PVDD during the transmission. Moreover, the first display region 111 having a larger light transmittance is generally smaller than the second display region 112 having a smaller light transmittance so that the area of the light shielding structure 712 in the second display region 112 is larger than the light shielding structure 711 in the first display region 111. In addition, the effect of the transmission impedance on the negative power supply signal PVEE is smaller than the effect of the transmission impedance on the positive power supply signal PVDD; therefore, the light shielding structure 712 in the second display region 112 can be electrically connected to the positive power supply signal PVDD having a higher potential, thereby reducing the transmission impedance of the positive power supply signal having the higher potential to a greater extent.

It can be understood that whether the light shielding layer is disposed between the active layer of the transistor and the substrate is related to the semiconductor material in the active layer of the transistor. Some semiconductor materials are more sensitive to the light so that the corresponding light shielding layer needs to be disposed between the active layer of the transistor and the substrate, while some semiconductor materials are less sensitive to the light so that the light shielding layer does not need to be disposed between the active layer of the transistor and the substrate under the premise of prioritizing the lightweight of the display panel. Therefore, whether the light shielding layer is disposed in the display panel can be designed as needed, and the embodiments of the present disclosure do not specifically limit thereto.

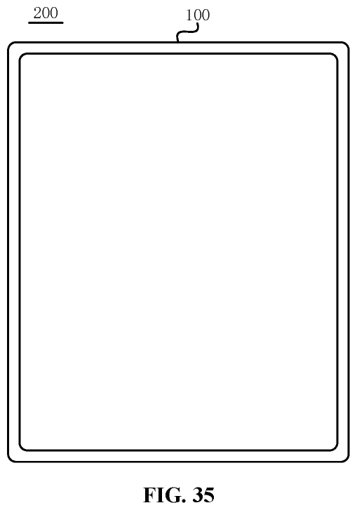

Based on the same inventive concept, an embodiment of the present disclosure also provides a display device. The display device includes the display panel of any one of the embodiments of the present disclosure. Therefore, the display device provided by the embodiment of the present disclosure includes the technical features of the display panel of any one of the embodiments of the present disclosure, and can achieve the beneficial effects of the display panel of any one of the embodiments of the present disclosure. Similarities can be referred to the preceding description of the display panel provided by the embodiments of the present disclosure, and will not be repeated herein. In an embodiment, as shown in FIG. 35, FIG. 35 is a view illustrating the structure of a display device according to an embodiment of the present disclosure. The display device 200 includes a display panel 100. The display device 200 may be any electronic product having the display function, including but not limited to: a television, a laptop, a desktop display, a tablet computer, a digital camera, a mobile phone, a smart bracelet, smart glasses, a vehicle-mounted display, medical equipment, industrial control equipment, a touch interactive terminal, etc.

The preceding embodiments of the present disclosure are not intended to limit the scope of the present disclosure. It can be understood by those skilled in the art that various modifications, combinations, sub-combinations and substitutions can be made according to design requirements and other factors.

Any modifications, equivalent replacements, improvements and the like within the spirit and principle of the present disclosure shall fall within the scope of the present disclosure.

What is claimed is:

1. A display panel, comprising:
a substrate; and
a plurality of pixel circuits located on a side of the substrate, wherein each of at least part of the plurality of pixel circuits comprises a first transistor; the first transistor comprises at least two active layers having different mobilities;
wherein the at least two active layers having different mobilities comprise a first active layer and a second active layer which are laminated; and a mobility of the first active layer is larger than a mobility of the second active layer.

2. The display panel of claim 1, wherein the first transistor further comprises a first gate; and the first gate is located on a side of the first active layer facing away from the second active layer.

3. The display panel of claim 2, wherein in a thickness direction of the display panel, the first gate overlaps the first active layer and the first gate overlaps the second active layer; and
in a first direction, a dimension of the first active layer is larger than a dimension of the second active layer, wherein the first direction is parallel to a plane where the substrate is located.

4. The display panel of claim 3, wherein the first transistor further comprises a first source and a first drain;
in the thickness direction of the display panel, an overlapping region of the first active layer with the first gate is a first channel region; the first active layer further comprises a first source region and a first drain region disposed in the first direction and the first source region and the first drain region are located on two opposite sides of the first channel region respectively; the first source is electrically connected to the first source region through a first via hole, and the first drain is electrically connected to the first drain region through a second via; and
in the thickness direction of the display panel, the first via does not overlap the second active layer and the second via does not overlap the second active layer.

5. The display panel of claim 2, wherein the first transistor further comprises a second gate; and
the second gate is located on a side of the second active layer facing away from the first active layer,
wherein the display panel further comprises:
a first gate insulating layer located between the first gate and the first active layer; and
a second gate insulating layer located between the second gate and the second active layer;
wherein a dielectric constant of the first gate insulating layer is larger than a dielectric constant of the second gate insulating layer.

6. The display panel of claim 5, wherein the first transistor further comprises a third active layer;
and a mobility of the third active layer is larger than the mobility of the second active layer; and
the third active layer is located between the second active layer and the second gate,
wherein a thickness of the second gate insulating layer is larger than a thickness of the first gate insulating layer.

7. The display panel of claim 6, wherein the first gate insulating layer has a dielectric constant of E1 and a thickness of D1, and the first gate has a vertical projection area of S1 on the first gate insulating layer; and the second gate insulating layer has a dielectric constant of E2 and a thickness of D2, and the second gate has a vertical projection area of S2 on the second gate insulating layer, wherein E1*S1/d1=E2*S2/d2.

8. The display panel of claim 5, further comprising:
a third gate insulating layer located between the second gate insulating layer and the second active layer;
wherein a dielectric constant of the third gate insulating layer is larger than a dielectric constant of the second gate insulating layer,
wherein the dielectric constant of the third gate insulating layer is larger than the dielectric constant of the first gate insulating layer, and
wherein the first gate insulating layer has a dielectric constant of E1, the second gate insulating layer has a dielectric constant of E2, and the third gate insulating layer has a dielectric constant of E3, wherein E3−E1=E1−E2.

9. The display panel of claim 2, further comprising:
a first gate insulating layer and a fourth gate insulating layer located between the first gate and the first active layer, wherein the fourth gate insulating layer is located on a side of the first gate insulating layer close to the first active layer;
wherein a dielectric constant of the fourth gate insulating layer is larger than a dielectric constant of the first gate insulating layer.

10. The display panel of claim 2, further comprising:
a plurality of light-emitting elements located on a side of the substrate, and the plurality of pixel circuits is electrically connected to the plurality of light-emitting elements;
wherein the first gate is configured to receive a data signal, and the first transistor is configured to provide a driving current for the light-emitting elements according to the data signal.

11. The display panel of claim 1, wherein the first transistor further comprises a second gate, and the second gate is located on a side of the second active layer facing away from the first active layer; and
the second gate is configured to receive a scanning signal and the first transistor is configured to be turned on or turned off under control of the scanning signal.

12. The display panel of claim 1, wherein the first transistor further comprises a third active layer; and a mobility of the third active layer is smaller than the mobility of the first active layer and is larger than the mobility of the second active layer; and
the third active layer is located between the first active layer and the second active layer.

13. The display panel of claim 1, wherein each of the at least two active layers of the first transistor comprises an oxide semiconductor, and the oxide semiconductor comprises indium; and
an indium content of the first active layer is larger than an indium content of the second active layer.

14. The display panel of claim 1, wherein each of the at least two active layers of the first transistor comprises an oxide semiconductor; and
the oxide semiconductor comprises InGaXO, wherein X comprises one of Zn, Zn—Sn and Sn, and X in the first active layer is different from X in the second active layer.

15. The display panel of claim 1, wherein a thickness of the second active layer is larger than a thickness of the first active layer.

16. The display panel of claim 1, wherein the each of at least part of the plurality of pixel circuits comprising the first transistor is a first pixel circuit, the first pixel circuit further comprises a second transistor, the second transistor comprises a fourth active layer, and the fourth active layer is disposed in a same layer as the second active layer or the fourth active layer is disposed in a same layer as the first active layer,
wherein the first pixel circuit further comprises a driving transistor; and
in a same first pixel circuit, the second transistor is configured to transmit a reset signal to the driving transistor to reset the driving transistor, and the first transistor is configured to transmit a compensation signal to the driving transistor to perform a threshold compensation on the driving transistor.

17. The display panel of claim 16, wherein the display panel further comprises a display region, wherein the display region comprises a first display region and a second display region, wherein a light transmittance of the second display region is smaller than a light transmittance of the first display region, and the second display region at least partially surrounds the first display region;
wherein the display panel further comprises: a second pixel circuit, wherein the second pixel circuit comprises a third transistor, the third transistor comprises a fifth active layer, and the fifth active layer is disposed in a same layer as the second active layer or the fifth active layer is disposed in a same layer as the first active layer; and
the second display region comprises the second pixel circuit, and the first display region comprises the first pixel circuit,
wherein the fifth active layer and the fourth active layer are disposed in a same layer and are made of a same material.

18. The display panel of claim 1, further comprising:
a light shielding layer located between the plurality of pixel circuits and the substrate, wherein the light shielding layer comprises a light shielding structure and the light shielding structure overlaps the active layer in a thickness direction of the display panel.

19. The display panel of claim 18, further comprising:
a display region, wherein the display region comprises a first display region and a second display region, wherein a light transmittance of the second display region is smaller than a light transmittance of the first display region, and the second display region at least partially surrounds the first display region; and
a light shielding structure located in the first display region is connected to a first potential, and a light shielding structure located in the second display region is connected to a second potential, and the second potential is larger than the first potential.

20. A display device, comprising: a display panel,
wherein the display panel comprises:
a substrate; and
a plurality of pixel circuits located on a side of the substrate, wherein each of at least part of the plurality of pixel circuits comprises a first transistor; the first transistor comprises at least two active layers having different mobilities;
wherein the at least two active layers having different mobilities comprise a first active layer and a second active layer which are laminated; and a mobility of the first active layer is larger than a mobility of the second active layer.
